(19) United States
(12) Patent Application Publication
(10) Pub. No.: US 2025/0072046 A1
(43) Pub. Date: Feb. 27, 2025

(54) SEMICONDUCTOR DEVICE, METHOD OF MANUFACTURING SEMICONDUCTOR DEVICE, AND POWER CONVERSION DEVICE

(71) Applicant: Mitsubishi Electric Corporation, Tokyo (JP)

(72) Inventors: Tetsuo TAKAHASHI, Tokyo (JP); Yutaka FUKUI, Tokyo (JP)

(73) Assignee: Mitsubishi Electric Corporation, Tokyo (JP)

(21) Appl. No.: 18/793,232

(22) Filed: Aug. 2, 2024

(30) Foreign Application Priority Data
Aug. 24, 2023 (JP) 2023-136183

(51) Int. Cl. H01L 29/78; H01L 29/66

(52) U.S. Cl. CPC H01L 29/7813; H01L 29/66734

(57) ABSTRACT

A second trench is disposed in an inactive region, is in contact with an active region, and includes a second sidewall including a longitudinal portion and a lateral portion, and a second bottom. A second bottom diffusion layer of a second conductivity type is disposed at least in a part of the second bottom. A second sidewall diffusion layer of the second conductivity type is disposed at least on one of the longitudinal portion and the lateral portion. A gate electrode includes a gate buried portion buried in each of first trenches, and a gate line portion extending from the gate buried portion into the second trench. A second bottom diffusion layer is disposed at least in a portion of the second bottom on which the gate line portion is disposed in a plan view.

### BACKGROUND OF THE INVENTION

### Field of the Invention

The present disclosure relates to a semiconductor device and a method of manufacturing the same.

### Description of the Background Art

Power semiconductor devices (more simply referred to as “power devices”) are used in, for example, switching elements for controlling supplying power to loads such as motors. The power devices have many requirements such as miniaturization, reducing weight, and achieving low loss. Achieving low loss is one of the highest requirements, and leads to environmentally friendly behaviors through reduction in energy consumption. Moreover, minimal reduction in cost is also required in fulfilling the requirements.

Semiconductor devices including insulated gates have widely been used as the aforementioned semiconductor devices, for example, an insulated-gate bipolar transistor (IGBT) and a metal-oxide-semiconductor field-effect transistor (MOSFET). Particularly, one widely used method is increasing channel densities using vertical trench gates as the insulated gates to reduce losses. Furthermore, recent years have seen proposals of adopting wide bandgap semiconductors such as silicon carbide (SiC) to improve the performance of semiconductor devices. For example, WO2017/138215, Japanese Patent Application Laid-Open No. 2015-126086, and Japanese Patent Application Laid-Open No. 2010-147222 disclose trench MOSFETs that can contain SiC as a semiconductor material.

In switching operations of the aforementioned trench gate switching elements, breakdown in insulating films such as a gate insulating film including, for example, an oxide film or a field insulating film immediately below a gate pad can be problematic. Particularly, when SiC is used as a semiconductor material, an increase in breakdown voltage and accelerating operations are expected more than by using Si. However, the increase in breakdown voltages and the accelerating operations make it difficult to ensure the reliability of the insulating films. Specifically, in the switching elements requiring increasing breakdown voltages, the field strength to be applied to the insulating films increases. Since dV/dt increases in the accelerating operations, the voltage increases due to a displacement current.

Particularly, a gate electrode in a trench gate switching element includes portions embedded into respective trenches formed in an active region, and a portion extending from the embedded portion into an inactive region (i.e., a region outside the active region). When the gate electrode faces a drift layer through a gate insulating film at a bottom or a sidewall of each of the trenches in the vicinity of a boundary between these portions, the gate electrode is susceptible to a potential of the drift layer. This easily causes the breakdown in the insulating film. One conceivable preventive measure against this is to form impurity diffusion layers with a conductivity type opposite to that of the drift layer at the bottom and the sidewall of each of the trenches. However, a trench structure including the diffusion layers with due consideration given to these has not fully been studied so far.

### SUMMARY

The present disclosure has been conceived to solve the problems, and has an object of providing a semiconductor device that can prevent dielectric breakdown of an insulating film facing a gate electrode in the vicinity of a boundary between an active region and an inactive region.

One aspect of the present disclosure is a semiconductor device including an active region and an inactive region in a plan view, the inactive region including a breakdown voltage holding region and a gate line region, the gate line region being in contact with the active region. The semiconductor device includes: a semiconductor substrate having a first main surface and a second main surface opposite to the first main surface; a first electrode disposed on the first main surface of the semiconductor substrate; a second electrode disposed on the second main surface of the semiconductor substrate; an insulating film on the first main surface of the semiconductor substrate; and a gate electrode on the first main surface through the insulating film.

The semiconductor substrate includes: a drift layer of a first conductivity type, the drift layer being disposed in the active region and the inactive region; a base region of a second conductivity type different from the first conductivity type, the base region being disposed in the active region between the drift layer and the first main surface; a first semiconductor region of the first conductivity type, the first semiconductor region being disposed on the base region in the active region and in contact with the first electrode; a plurality of first trenches in the first main surface in the active region, the first trenches including a first bottom and a first sidewall, the first sidewall being in contact with the first semiconductor region and the base region, each of the first trenches extending in a longitudinal direction, the first trenches being aligned in a lateral direction crossing the longitudinal direction; a first bottom diffusion layer of the second conductivity type, the first bottom diffusion layer being disposed on the first bottom of each of the first trenches; a first sidewall diffusion layer of the second conductivity type, the first sidewall diffusion layer being disposed on the first sidewall of each of the first trenches and in contact with the first bottom diffusion layer and the base region; a second semiconductor region of the first conductivity type or the second conductivity type, the second semiconductor region being disposed between the drift layer and the second main surface at least in the active region and in contact with the second electrode; a second trench in the first main surface in the inactive region, the second trench including a second bottom and a second sidewall, the second sidewall including a longitudinal portion along the longitudinal direction and being in contact with the active region, and a lateral portion along the lateral direction; a second bottom diffusion layer of the second conductivity type, the second bottom diffusion layer being disposed at least in a part of the second bottom of the second trench; and a second sidewall diffusion layer of the second conductivity type, the second sidewall diffusion layer being disposed at least on the longitudinal portion or the lateral portion of the second sidewall of the second trench, and being in contact with the second bottom diffusion layer and the base region. The gate electrode includes: a gate buried portion buried in each of the first trenches of the semiconductor substrate through the insulating film; and a gate line portion extending from the gate buried portion into the second trench. The second bottom diffusion layer is disposed at least in a portion of the second bottom of the second trench on which the gate line portion is disposed in the plan view.

According to the one aspect of the present disclosure, the second sidewall diffusion layer disposed on the second sidewall of the second trench is in contact with each of the second bottom diffusion layer disposed at least in a part of the second bottom of the second trench, and the base region having a potential of the first electrode. Consequently, the second sidewall in contact with the active region and the second bottom extending from the second sidewall toward the inactive region can avoid excessive potential rise, through electrical connection to the potential of the first electrode. Thus, it is possible to prevent dielectric breakdown of the insulating film facing the gate electrode in the vicinity of the boundary between the active region and the inactive region.

The objects, features, aspects, and advantages of the present disclosure will become more apparent from the following detailed description and the accompanying drawings.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a plan view schematically illustrating a layout of a semiconductor device according to Embodiment 1;

FIG. 2 is a partial plan view of a dashed line region II in FIG. 1 which schematically illustrates a structure of the semiconductor device according to Embodiment 1;

FIG. 3 is a partial cross-sectional view taken along the line III-III in FIG. 2 which schematically illustrates the structure of the semiconductor device according to Embodiment 1;

FIG. 4 is a partial cross-sectional view taken along the line IV-IV in FIG. 2 which schematically illustrates the structure of the semiconductor device according to Embodiment 1;

FIG. 5 is a partial cross-sectional view taken along the line V-V in FIG. 2 which schematically illustrates the structure of the semiconductor device according to Embodiment 1;

FIG. 6 is a partial cross-sectional view taken along the line VI-VI in FIG. 2 which schematically illustrates the structure of the semiconductor device according to Embodiment 1;

FIG. 7 is a partial cross-sectional view corresponding to FIG. 3 which schematically illustrates the first step of a method of manufacturing the semiconductor device according to Embodiment 1;

FIG. 8 is a partial cross-sectional view corresponding to FIG. 5 which schematically illustrates the first step of the method of manufacturing the semiconductor device according to Embodiment 1;

FIG. 9 is a partial cross-sectional view corresponding to FIG. 3 which schematically illustrates the second step of the method of manufacturing the semiconductor device according to Embodiment 1;

FIG. 10 is a partial cross-sectional view corresponding to FIG. 5 which schematically illustrates the second step of the method of manufacturing the semiconductor device according to Embodiment 1;

FIG. 11 is a partial cross-sectional view corresponding to FIG. 3 which schematically illustrates the third step of the method of manufacturing the semiconductor device according to Embodiment 1;

FIG. 12 is a partial cross-sectional view corresponding to FIG. 5 which schematically illustrates the third step of the method of manufacturing the semiconductor device according to Embodiment 1;

FIG. 13 is a partial cross-sectional view corresponding to FIG. 3 which schematically illustrates the fourth step of the method of manufacturing the semiconductor device according to Embodiment 1;

FIG. 14 is a partial cross-sectional view corresponding to FIG. 5 which schematically illustrates the fourth step of the method of manufacturing the semiconductor device according to Embodiment 1;

FIG. 15 is a partial cross-sectional view corresponding to FIG. 3 which schematically illustrates the fifth step of the method of manufacturing the semiconductor device according to Embodiment 1;

FIG. 16 is a partial cross-sectional view corresponding to FIG. 5 which schematically illustrates the fifth step of the method of manufacturing the semiconductor device according to Embodiment 1;

FIG. 17 is a partial cross-sectional view corresponding to FIG. 3 which schematically illustrates the sixth step of the method of manufacturing the semiconductor device according to Embodiment 1;

FIG. 18 is a partial cross-sectional view corresponding to FIG. 5 which schematically illustrates the sixth step of the method of manufacturing the semiconductor device according to Embodiment 1;

FIG. 19 is a plan view schematically illustrating a layout of a semiconductor device according to Embodiment 2;

FIG. 20 is a partial plan view of a dashed line region XX in FIG. 19 which schematically illustrates a structure of the semiconductor device according to Embodiment 2;

FIG. 21 is a partial cross-sectional view taken along the line XXI-XXI in FIG. 20 which schematically illustrates the structure of the semiconductor device according to Embodiment 2;

FIG. 22 is a partial cross-sectional view taken along the line XXII-XXII in FIG. 20 which schematically illustrates the structure of the semiconductor device according to Embodiment 2;

FIG. 23 is a partial cross-sectional view taken along the line XXIII-XXIII in FIG. 20 which schematically illustrates the structure of the semiconductor device according to Embodiment 2;

FIG. 24 is a partial cross-sectional view taken along the line XXIV-XXIV in FIG. 20 which schematically illustrates the structure of the semiconductor device according to Embodiment 2;

FIG. 25 is a plan view schematically illustrating a layout of a semiconductor device according to Embodiment 3;

FIG. 26 is a partial plan view of a dashed line region XXVI in FIG. 25 which schematically illustrates a structure of the semiconductor device according to Embodiment 3;

FIG. 27 is a partial cross-sectional view taken along the line XXVII-XXVII in FIG. 26 which schematically illustrates the structure of the semiconductor device according to Embodiment 3;

FIG. 28 is a partial cross-sectional view taken along the line XXVIII-XXVIII in FIG. 26 which schematically illustrates the structure of the semiconductor device according to Embodiment 3;

FIG. 29 is a partial cross-sectional view taken along the line XXIX-XXIX in FIG. 26 which schematically illustrates the structure of the semiconductor device according to Embodiment 3;

FIG. 30 is a partial cross-sectional view taken along the line XXX-XXX in FIG. 26 which schematically illustrates the structure of the semiconductor device according to Embodiment 3;

FIG. 31 is a plan view schematically illustrating a layout of a semiconductor device according to Embodiment 4;

FIG. 32 is a partial plan view of a dashed line region XXXII in FIG. 31 which schematically illustrates a structure of the semiconductor device according to Embodiment 4;

FIG. 33 is a partial cross-sectional view taken along the line XXXIII-XXXIII in FIG. 32 which schematically illustrates the structure of the semiconductor device according to Embodiment 4;

FIG. 34 is a partial cross-sectional view taken along the line XXXIV-XXXIV in FIG. 32 which schematically illustrates the structure of the semiconductor device according to Embodiment 4;

FIG. 35 is a partial cross-sectional view taken along the line XXXV-XXXV in FIG. 32 which schematically illustrates the structure of the semiconductor device according to Embodiment 4;

FIG. 36 is a partial cross-sectional view taken along the line XXXVI-XXXVI in FIG. 32 which schematically illustrates the structure of the semiconductor device according to Embodiment 4; and

FIG. 37 is a block diagram schematically illustrating a configuration of a power conversion system including a power conversion device according to Embodiment 5.

### DESCRIPTION OF THE PREFERRED EMBODIMENTS

Embodiments will be described with reference to drawings. The same reference numerals are assigned to the same or equivalent portions in the drawings, and the description is not repeated.

### Embodiment 1

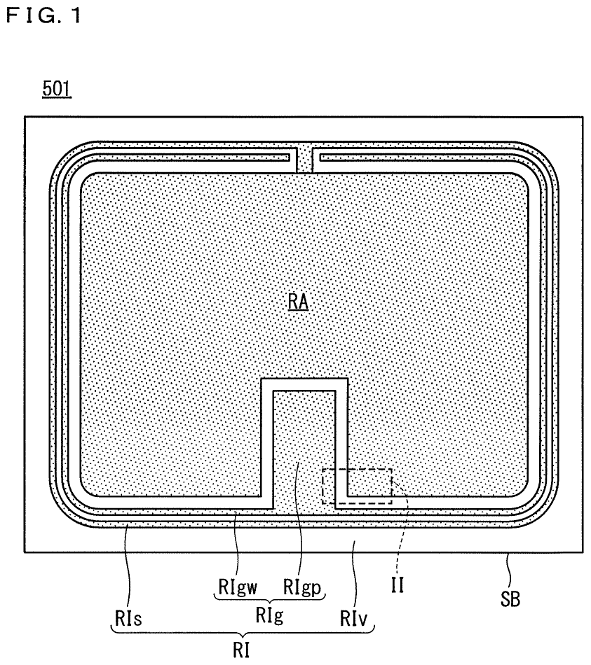

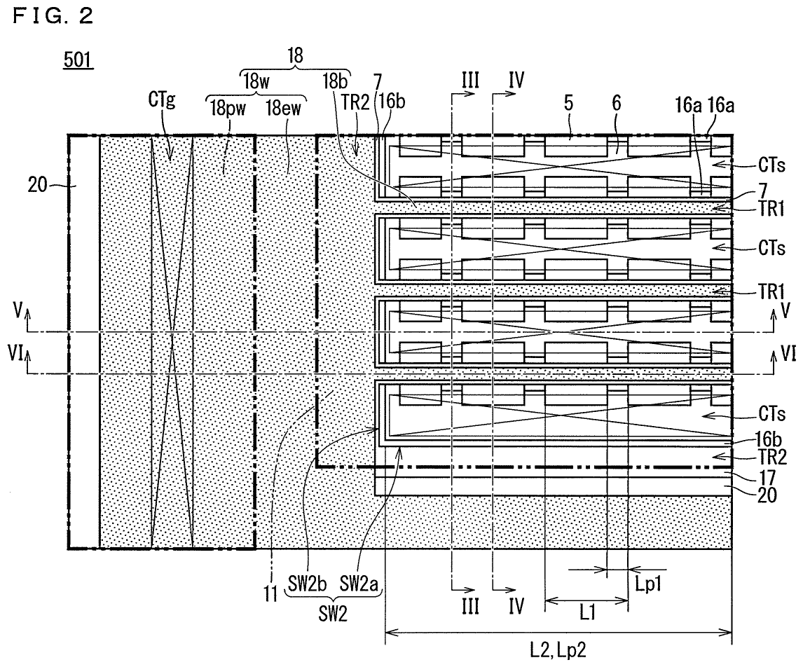

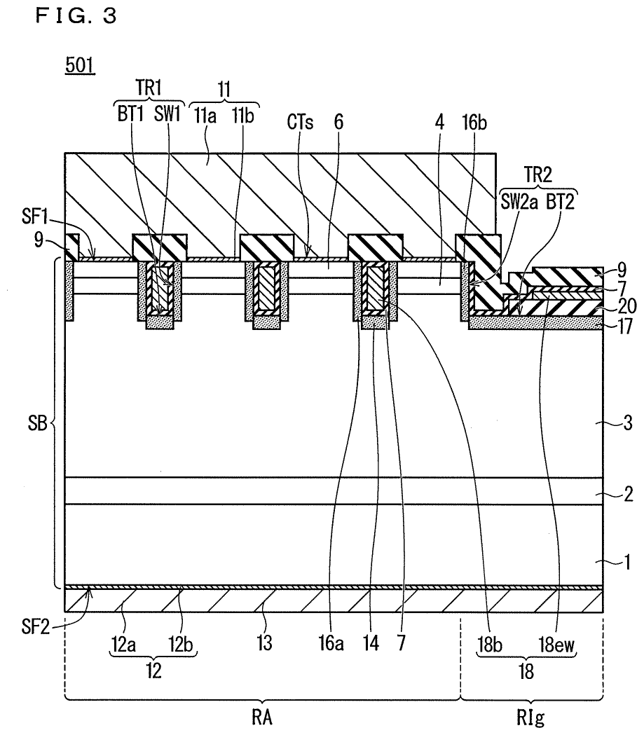

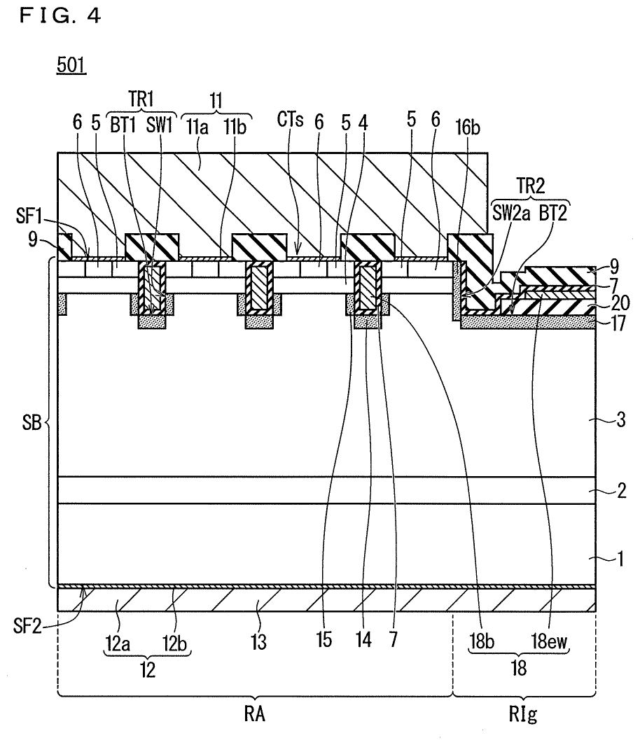

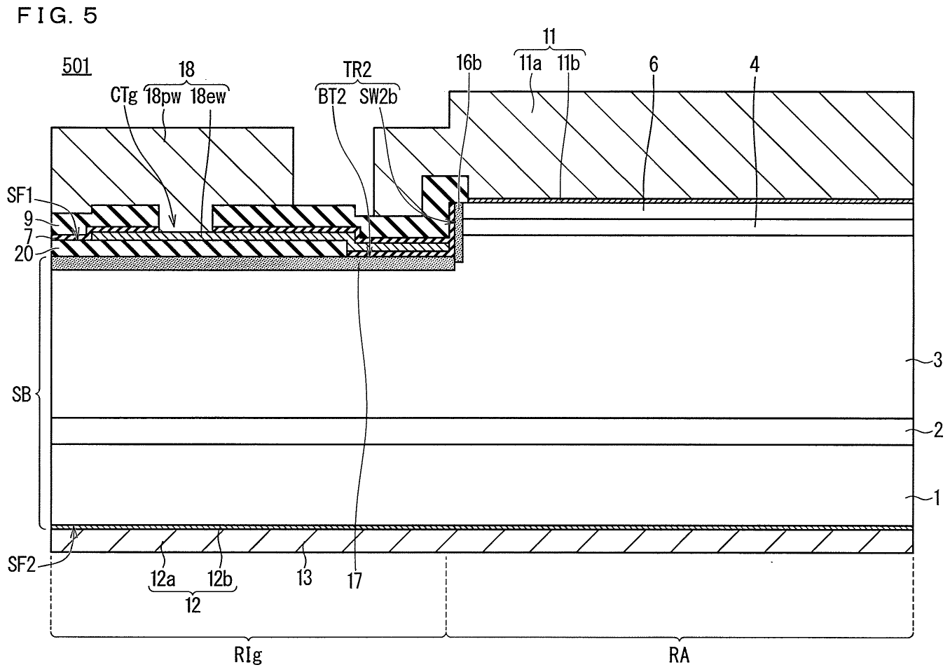

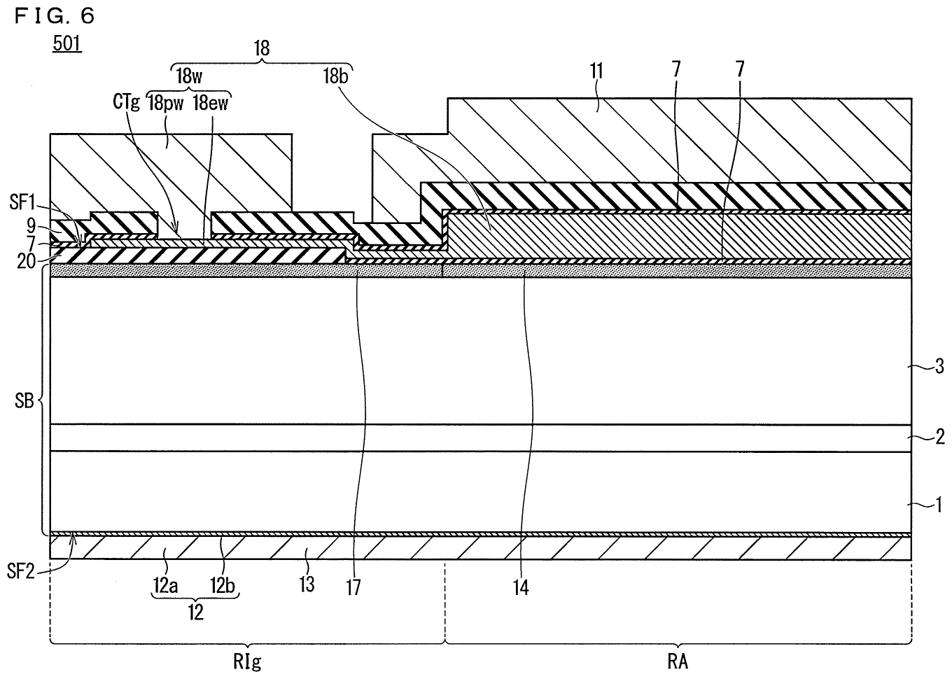

FIG. 1 is a plan view schematically illustrating a layout of a semiconductor device 501 according to Embodiment 1. FIG. 2 is a partial plan view of a dashed line region II in FIG. 1 which schematically illustrates a structure of the semiconductor device 501. FIG. 3 is a partial cross-sectional view taken along the line III-III in FIG. 2 which schematically illustrates the structure of the semiconductor device 501. FIG. 4 is a partial cross-sectional view taken along the line IV-IV in FIG. 2 which schematically illustrates the structure of the semiconductor device 501. FIG. 5 is a partial cross-sectional view taken along the line V-V in FIG. 2 which schematically illustrates the structure of the semiconductor device 501. FIG. 6 is a partial cross-sectional view taken along the line VI-VI in FIG. 2 which schematically illustrates the structure of the semiconductor device 501. The dotted pattern in FIG. 1 illustrates an example pattern of an entire surface electrode on an upper surface SF1 of a semiconductor substrate SB. The dotted pattern in FIG. 2 illustrates a pattern of gate buried portions 18b and an interconnection 18ew that are parts of a gate electrode 18 (typically, a pattern of a polysilicon layer). FIG. 2 illustrates, using two-dot chain lines, only edges of a gate surface electrode 18pw of the gate electrode 18 and a source electrode 11 to facilitate viewing of an internal structure of the semiconductor device 501. FIG. 2 omits the illustration of an interlayer insulating film 9, and illustrates contact portions CTs and a contact portion CTg penetrating the interlayer insulating film 9, using rectangles with X marks.

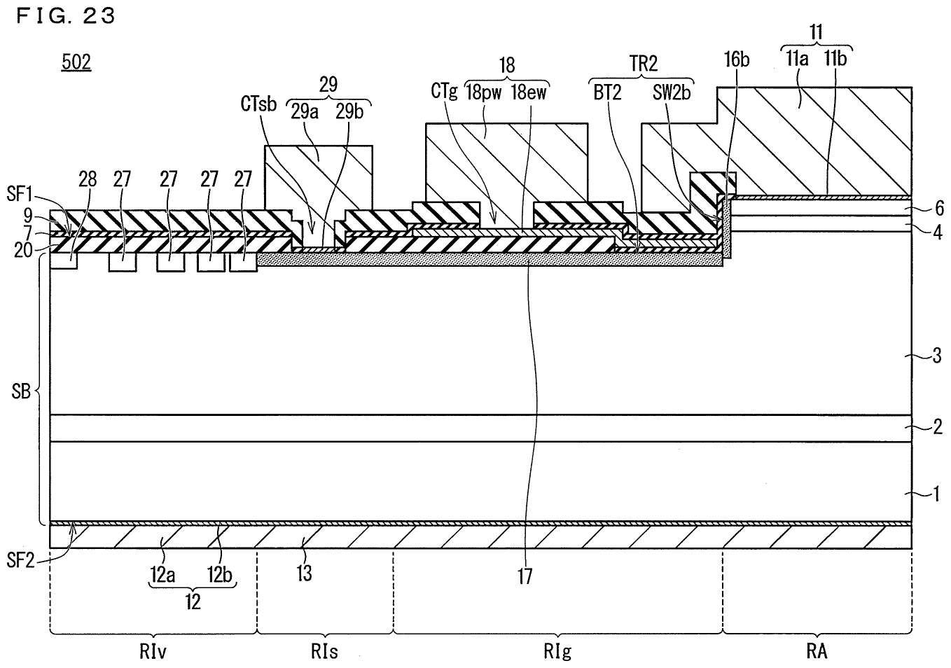

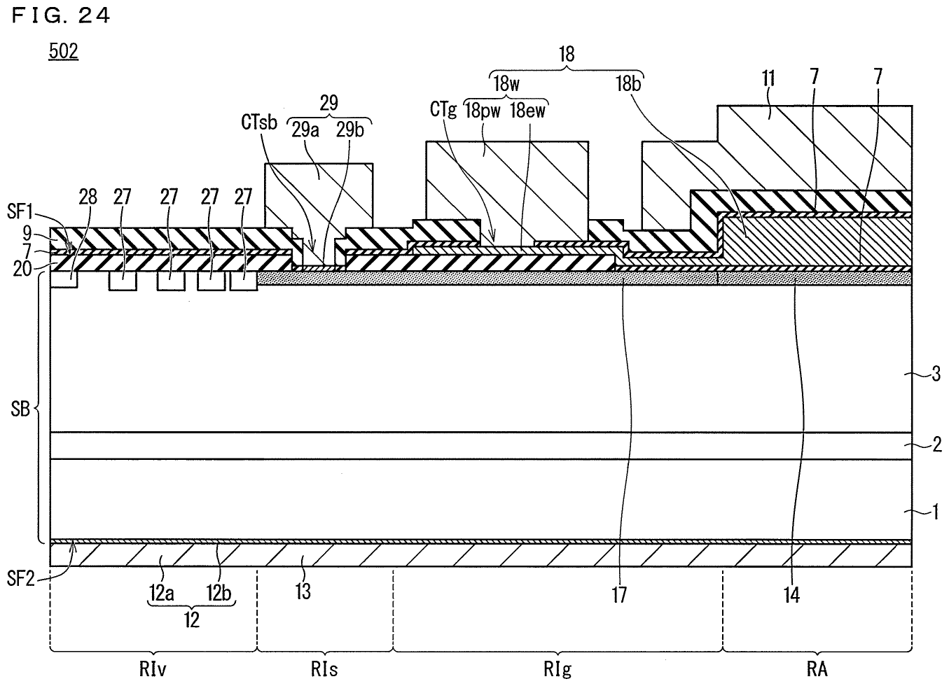

The semiconductor device 501 includes the semiconductor substrate SB. The semiconductor device 501 includes an active region RA and an inactive region RI in a plan view of the semiconductor substrate SB. On the semiconductor substrate SB, the active region RA is a portion in which actual elements are produced, and the inactive region RI is a portion in which actual elements are not produced. The active region RA may be formed by approximately periodically disposing a plurality of cell structures each with approximately the same structure. The inactive region RI includes a breakdown voltage holding region RIv, and a gate line region RIg in contact with the active region RA. The gate line region RIg may include a pad region RIgp and an interconnection region RIgw. The inactive region R1 may further include a source line region RIs. The breakdown voltage holding region RIv is a region for maintaining the breakdown voltage of the semiconductor device 501, and preferably surrounds the active region RA. In the breakdown voltage holding region RIv, regions for maintaining the breakdown voltage are preferably formed on the upper surface SF1 by doping impurities. For example, field limiting rings (FLR) 27 as illustrated in FIGS. 23 and 24 and referred to in Embodiment 2 to be described later are formed. The FLRs 27 have a conductivity type different from that of an n drift layer 3. The gate line region RIg is a region in which a gate line portion 18w to be described later in detail is disposed. The source line region RIs is a region in which a source line portion 29 (see FIGS. 23 and 24 to be described later) that is a part of the source electrode 11 is disposed.

The semiconductor substrate SB has the upper surface SF1 (a first main surface), and a lower surface SF2 (a second main surface opposite to the first main surface). The upper surface SF1 of the semiconductor substrate SB includes an approximately flat portion, and a plurality of trenches that are portions lower than this flat portion, specifically, a plurality of first trenches TR1 and at least one second trench TR2. The semiconductor substrate SB is, but not exclusively, made of Si or SiC, for example. The semiconductor device 501 includes the source electrode 11 (a first electrode), a drain electrode 12 (a second electrode), the gate electrode 18, a gate insulating film 7, a field insulating film 20, and the interlayer insulating film 9, in addition to the semiconductor substrate SB. The semiconductor device 501 according to Embodiment 1 is a vertical MOSFET that switches a main current flowing between the source electrode 11 on the upper surface SF1 and the drain electrode 12 on the lower surface SF2, and has a trench gate structure controlled by a potential of the gate electrode 18. This trench gate structure includes an n⁺ source layer 5, a p channel doped layer 4, the n drift layer 3, the gate insulating film 7, and the gate buried portions 18b of the gate electrode 18.

The source electrode 11 is disposed on the upper surface SF1 of the semiconductor substrate SB. The source electrode 11 may include a silicide layer 11b in contact with the semiconductor substrate SB, and a non-silicide layer 11a laminated on the silicide layer 11b. The drain electrode 12 is disposed on the lower surface SF2 of the semiconductor substrate SB. The drain electrode 12 may include a silicide layer 12b (a barrier metal layer) in contact with the semiconductor substrate SB, and a top metal layer 12a laminated on the silicide layer 12b. The non-silicide layer 11a and the top metal layer 12a may be made of, for example, an electrode material containing aluminum.

The gate insulating film 7, the field insulating film 20, and the interlayer insulating film 9 are disposed on the upper surface SF1 of the semiconductor substrate SB. The interlayer insulating film 9 separates the source electrode 11 from the gate electrode 18 in a thickness direction (a vertical direction in FIGS. 3 to 6). The gate electrode 18 is disposed on the upper surface SF1 through one of the gate insulating film 7 and the field insulating film 20. The field insulating film 20 may be thicker than the gate insulating film 7.

The semiconductor substrate SB includes the n⁻ drift layer 3 of n-type (a first conductivity type), the p channel doped layer 4 (a base region) of p-type (a second conductivity type different from the first conductivity type), the n⁺ source layer 5 (a first semiconductor region) of the first semiconductor type, a p⁺ contact layer 6 (a contact region) of p-type, first bottom diffusion layers 14 of p-type, first sidewall diffusion layers 16a of p-type, an n⁺ substrate 1 (a second semiconductor region) of n-type, a second bottom diffusion layer 17 of p-type, and second sidewall diffusion layers 16b of p-type. The semiconductor substrate SB may further include an n⁺ buffer layer 2 of n-type between the n⁺ substrate 1 and the n drift layer 3. The semiconductor substrate SB may further include a sidewall diffusion layer 15 of n-type.

The n drift layer 3 is disposed in the active region RA and the inactive region RI. The n⁺ substrate 1 is disposed at least in the active region RA, and is disposed between the n drift layer 3 and the lower surface SF2. The n⁺ substrate 1 is in contact with the drain electrode 12.

The p channel doped layer 4 is disposed in the active region RA, and is disposed between the n⁻ drift layer 3 and the upper surface SF1.

The n⁺ source layer 5 is disposed in the active region RA, and is disposed on the p channel doped layer 4. The n⁺ source layer 5 is in contact with the source electrode 11.

The plurality of first trenches TR1 are disposed in the upper surface SF1 in the active region RA. Each of the first trenches TR1 includes a first sidewall SW1 in contact with the n⁺ source layer 5 and the p channel doped layer 4, and a first bottom BT1. The plurality of first trenches TR1 extend in the longitudinal direction (a horizontal direction in FIG. 2). The plurality of first trenches TR1 are aligned in a lateral direction crossing the longitudinal direction. The lateral direction may be orthogonal to the longitudinal direction.

The first bottom diffusion layer 14 is disposed on each of the first bottoms BT1 of the first trenches TR1. The first sidewall diffusion layer 16a is disposed on a part of each of the first sidewalls SW1 of the first trenches TR1. The first sidewall diffusion layer 16a is in contact with the first bottom diffusion layer 14 and the p channel doped layer 4. The sidewall diffusion layer 15 of n-type in contact with the n drift layer 3 may be disposed on a portion of the first sidewall SW1 where the first sidewall diffusion layer 16a of p-type is absent.

The second trench TR2 is disposed in the upper surface SF1 in the inactive region RI, and is in contact with the active region RA. The second trench TR2 includes a second sidewall SW2 and a second bottom BT2. The second sidewall SW2 includes a longitudinal portion SW2a along the longitudinal direction, and a lateral portion SW2b along the lateral direction. In the partial plan view of FIG. 2, the second trench TR2 extends in an L-shape. The second trench TR2 may surround the active region RA in an entire plan view of the semiconductor device 501. The plurality of first trenches TR1 may be directly connected to the second trench TR2. In FIG. 2, the left ends of the first trenches TR1 are directly connected to the second trench TR2. The width (a horizontal dimension in FIG. 3 or 4) of the second trench TR2 may be greater than that of the first trench TR1.

The second bottom diffusion layer 17 is disposed at least in a part of the second bottom BT2 of the second trench TR2.

The second sidewall diffusion layer 16b is disposed at least on one of the longitudinal portion SW2a and the lateral portion SW2b of the second sidewall SW2 of the second trench TR2. As illustrated in FIGS. 2 to 6, the second sidewall diffusion layer 16b may be disposed on each of the longitudinal portion SW2a and the lateral portion SW2b of the second sidewall SW2 of the second trench TR2. The second sidewall diffusion layer 16b may be disposed on the whole of the longitudinal portion SW2a of the second sidewall SW2 of the second trench TR2. The second sidewall diffusion layer 16b may be disposed on the whole of the lateral portion SW2b of the second sidewall SW2 of the second trench TR2. The second sidewall diffusion layers 16b are in contact with the second bottom diffusion layer 17 and the p channel doped layer 4.

The second sidewall diffusion layer 16b may surround the active region RA in a plan view. As illustrated in FIG. 2, when the second sidewall SW2 of the second trench TR2 is connected to end faces of the first trenches TR1 (the left ends of the first trenches TR1 in FIG. 2) and the second sidewall diffusion layers 16b surround the active region RA through the end faces in a plan view, the second sidewall diffusion layers 16b are assumed to surround the active region RA in a plan view.

The source electrode 11 includes at least one of the contact portions CTs in contact with the upper surface SF1 of the semiconductor substrate SB outside the second trench TR2. The plurality of contact portions CTs (the rectangles with X marks) extending in the longitudinal direction are aligned in the lateral direction (the vertical direction in FIG. 2), in a view of an upper right portion (outside of the second trench TR2 extending in an L-shape to the left of and below the view) in FIG. 2. The source electrode 11 may include the contact portion CTs between the second trench TR2 and the first trench TR1 the closest to the second trench TR2 from among the plurality of first trenches TR1 in the lateral direction. This contact portion CTs corresponds to the contact portion CTs disposed at the bottom in the view of FIG. 2.

The p⁺ contact layer 6 is in contact with the contact portion CTs of the source electrode 11, specifically, in contact with the silicide layer 11b of the source electrode 11. The p⁺ contact layer 6 is in contact with the p channel doped layer 4. Furthermore, the p⁺ contact layer 6 may be in contact with the second sidewall diffusion layer 16b. Here, the contact portion CTs is electrically connected to the second sidewall diffusion layer 16b through the p⁺ contact layer 6.

The gate electrode 18 includes the gate buried portions 18b and the gate line portion 18w. The gate buried portion 18b is buried in each of the first trenches TR1 of the semiconductor substrate SB through the gate insulating film 7. The gate buried portions 18b are made of, for example, polysilicon. The gate line portion 18w extends from the gate buried portion 18b into the second trench TR2. The second bottom diffusion layer 17 is disposed at least in a portion of the second bottom BT2 of the second trench TR2 where the gate line portion 18w is disposed in a plan view.

The gate line portion 18w may include the interconnection 18ew and the gate surface electrode 18pw. The interconnection 18ew is directly connected to the gate buried portions 18b. The interconnection 18ew and the gate buried portions 18b may be made of the same material, for example, polysilicon. The gate surface electrode 18pw in the pad region RIgp (FIG. 1) can be used as a part to which a line (e.g., a bonding wire) for applying a gate potential to the semiconductor device 501 is connected. The gate surface electrode 18pw includes the contact portion CTg in contact with the interconnection 18ew. A p-type diffusion layer that is the second bottom diffusion layer 17 or the p⁺ contact layer 6 may be disposed in a portion overlapping the gate surface electrode 18pw in a plan view on the upper surface SF1 of the semiconductor substrate SB. Disposing the interconnection 18ew on the field insulating film 20 in the portion overlapping the gate surface electrode 18pw in the plan view may separate the interconnection 18ew from the semiconductor substrate SB.

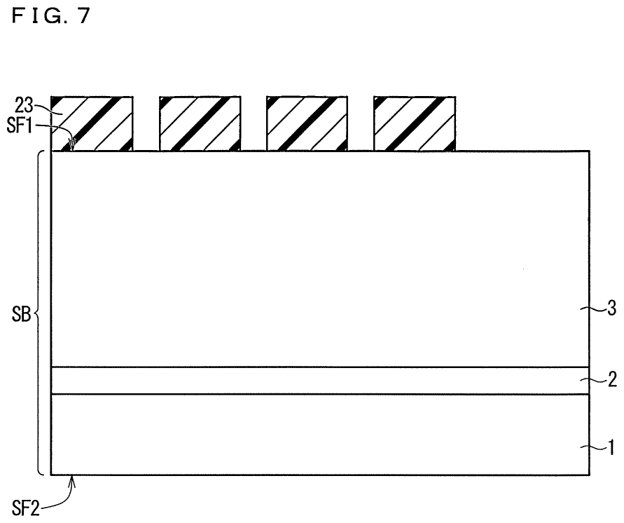

Next, a method of manufacturing the semiconductor device 501, particularly, a step of forming the first trenches TR1 each including inner surfaces with the first bottom diffusion layer 14 and the first sidewall diffusion layer 16a, and the second trench TR2 including inner surfaces with the second bottom diffusion layer 17 and the second sidewall diffusion layer 16b will be described hereinafter with reference to FIGS. 7 to 18.

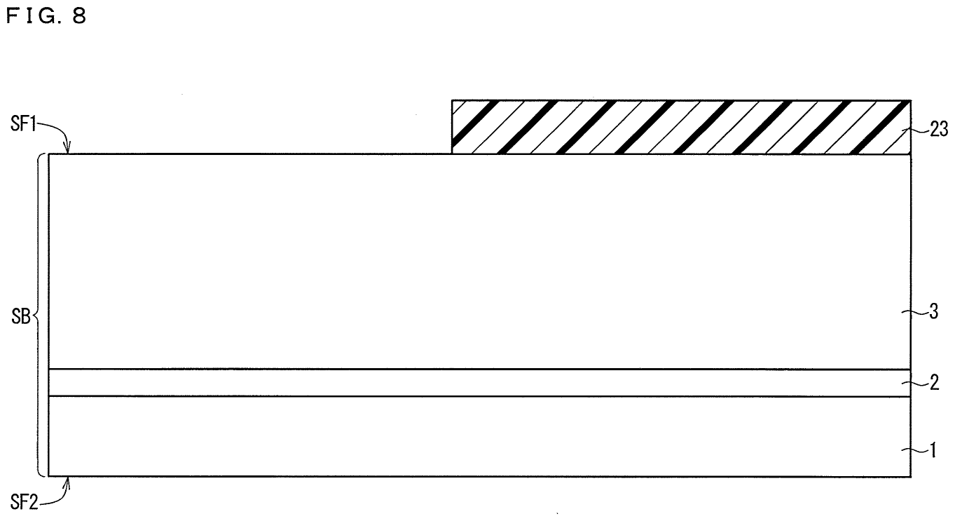

FIG. 7 and FIG. 8 are partial cross-sectional views corresponding to FIG. 3 and FIG. 5, respectively, which schematically illustrate the first step of the method of manufacturing the semiconductor device 501. First, the semiconductor substrate SB including the n⁺ substrate 1, and the n⁺ buffer layer 2 and the n⁻ drift layer 3 laminated on the n⁺ substrate 1 in this order is prepared. Next, an etch mask material 23 is formed on the upper surface SF1 of the semiconductor substrate SB through, for example, general photolithography. The etch mask material 23 may include, for example, a photoresist film or a plasma insulated film formed using the photoresist film.

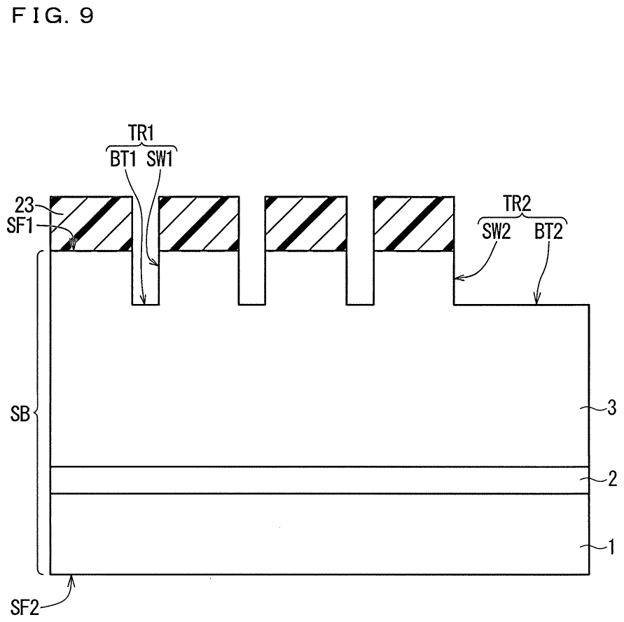

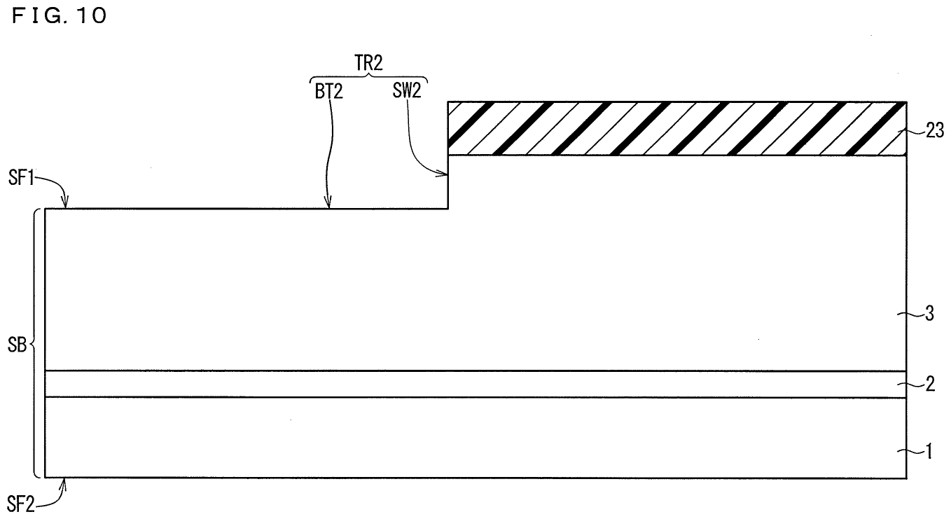

FIG. 9 and FIG. 10 are partial cross-sectional views corresponding to FIG. 3 and FIG. 5, respectively, which schematically illustrate the second step of the method of manufacturing the semiconductor device 501. In this step, etching is performed using the etch mask material 23. This forms the first trenches TR1 and the second trench TR2.

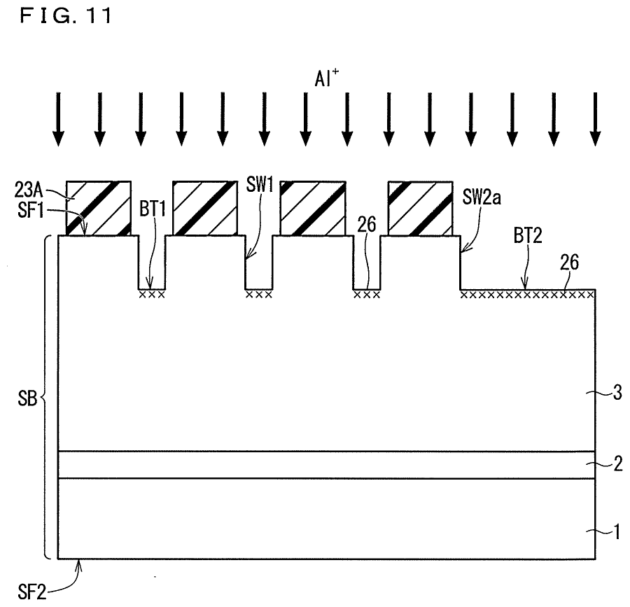

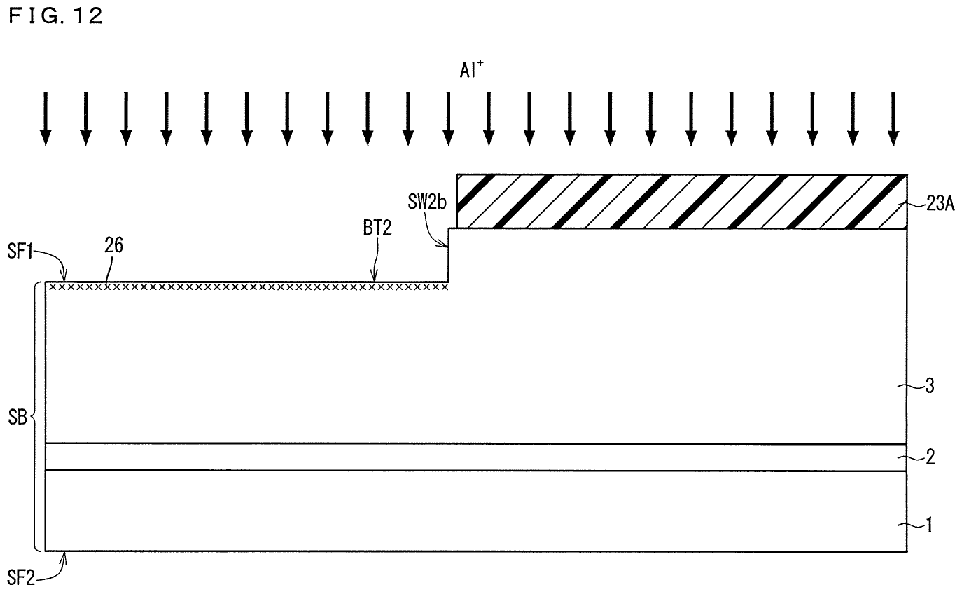

FIG. 11 and FIG. 12 are partial cross-sectional views corresponding to FIG. 3 and FIG. 5, respectively, which schematically illustrate the third step of the method of manufacturing the semiconductor device 501. First, an etch mask material 23A is formed on the upper surface SF1 of the semiconductor substrate SB through, for example, general photolithography. The etch mask material 23 (FIGS. 9 and 10) may also be used as a part or the entirety of the etch mask material 23A, instead of newly forming the entirety of the etch mask material 23A. Next, implanting ions using the etch mask material 23A forms impurity implantation regions 26. Ions are implanted approximately vertically on the semiconductor substrate SB so that the ions are efficiently implanted into the first bottoms BT1 of the first trenches TR1 and the second bottom BT2 of the second trench TR2 without substantially influencing the first sidewalls SW1 of the first trenches TR1 and the second sidewall SW2 of the second trench TR2. This third step may be performed after fourth and fifth steps to be described later as a modification.

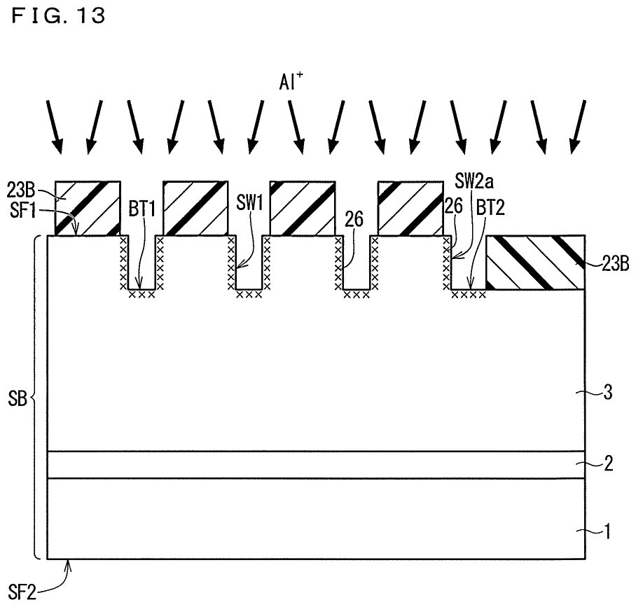

Next, obliquely implanting ions into the first sidewalls SW1 of the first trenches TR1 and the second sidewall SW2 of the second trench TR2 with respect to the semiconductor substrate SB forms impurity implantation regions for forming the first sidewall diffusion layers 16a (FIG. 3) and the second sidewall diffusion layer 16b (FIG. 5). This step will be described hereinafter with reference to FIGS. 13 to 16.

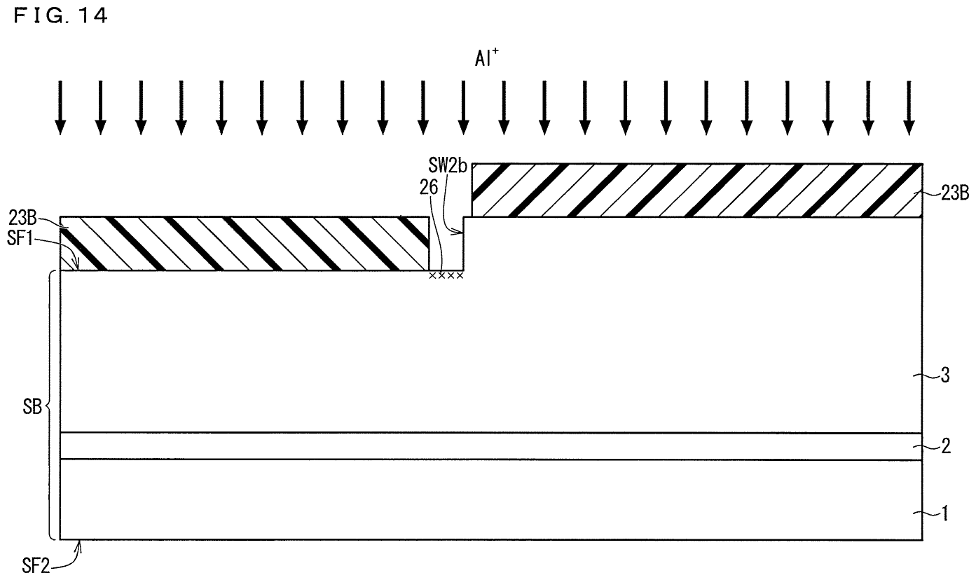

FIG. 13 and FIG. 14 are partial cross-sectional views corresponding to FIG. 3 and FIG. 5, respectively, which schematically illustrate the fourth step of the method of manufacturing the semiconductor device 501. First, an etch mask material 23B is formed on the upper surface SF1 of the semiconductor substrate SB through, for example, general photolithography. The etch mask material 23 or the etch mask material 23A may also be used as a part or the entirety of the etch mask material 23B, instead of newly forming the entirety of the etch mask material 23B. Next, implanting ions using the etch mask material 23B forms the impurity implantation regions 26. A direction in which the ions are implanted is set in this step so that the ions are efficiently implanted into the first sidewalls SW1 of the first trenches TR1 and the longitudinal portion SW2a of the second sidewall SW2 of the second trench TR2 without substantially influencing the lateral portion SW2b of the second sidewall SW2 of the second trench TR2. Specifically, the direction in which the ions are implanted is set so that ion beams are efficiently incident on the first sidewalls SW1 of the first trenches TR1 and the longitudinal portion SW2a of the second sidewall SW2 of the second trench TR2 (see FIG. 13) without substantially making ion beams incident on the lateral portion SW2b of the second sidewall SW2 of the second trench TR2 (see FIG. 14). Thus, ions are implanted not substantially into the lateral portion SW2b of the second sidewall SW2 of the second trench TR2 but into the longitudinal portion SW2a of the second sidewall SW2 of the second trench TR2 in this step. Implanting ions in this fourth step may be performed after the fifth step to be described later as a modification.

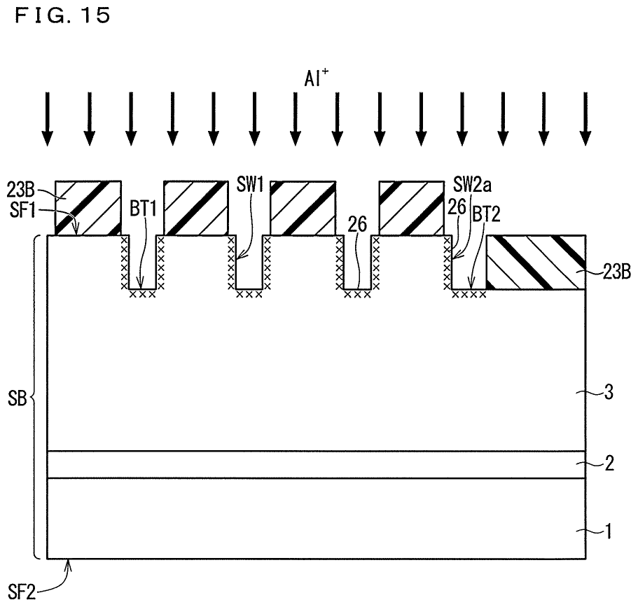

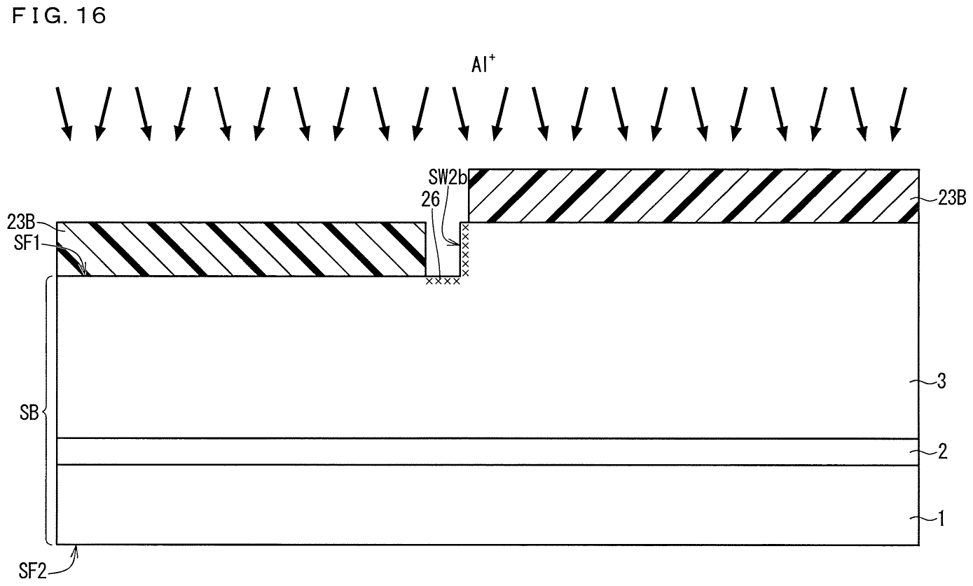

FIG. 15 and FIG. 16 are partial cross-sectional views corresponding to FIG. 3 and FIG. 5, respectively, which schematically illustrate the fifth step of the method of manufacturing the semiconductor device 501. Implanting ions using the etch mask material 23B forms the impurity implantation regions 26. A direction in which ions are implanted is set in this step so that the ions are efficiently implanted into the lateral portion SW2b of the second sidewall SW2 of the second trench TR2 without substantially influencing the first sidewalls SW1 of the first trenches TR1 and the longitudinal portion SW2a of the second sidewall SW2 of the second trench TR2. Specifically, the direction in which ions are implanted is set so that ion beams are efficiently incident on the lateral portion SW2b of the second sidewall SW2 of the second trench TR2 (see FIG. 16) without substantially making ion beams incident on the first sidewalls SW1 of the first trenches TR1 and the longitudinal portion SW2a of the second sidewall SW2 of the second trench TR2 (see FIG. 15). Thus, ions are implanted not substantially into the longitudinal portion SW2a of the second sidewall SW2 of the second trench TR2 but into the lateral portion SW2b of the second sidewall SW2 of the second trench TR2 in this step.

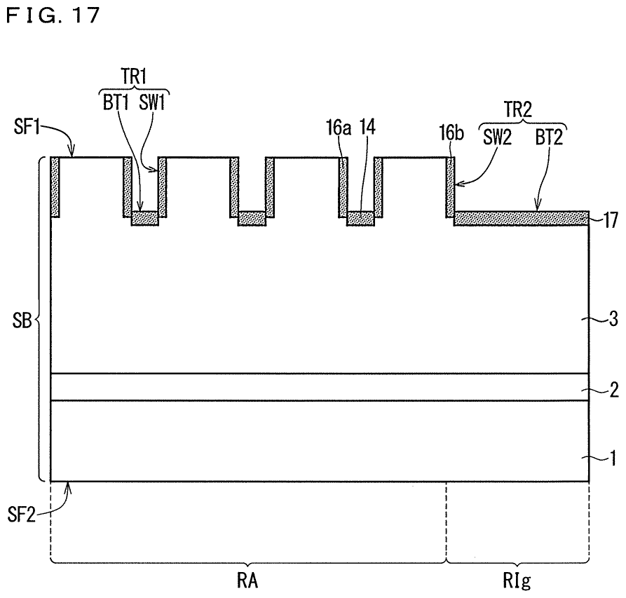

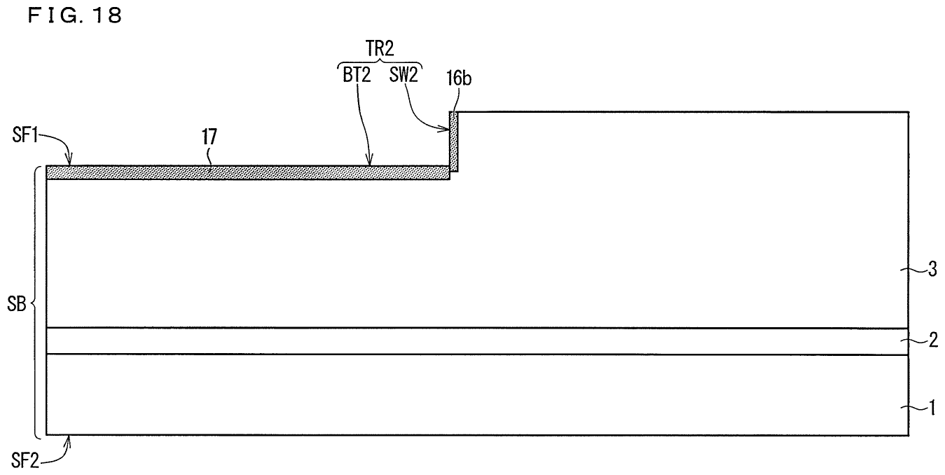

FIG. 17 and FIG. 18 are partial cross-sectional views corresponding to FIG. 3 and FIG. 5, respectively, which schematically illustrate the sixth step of the method of manufacturing the semiconductor device 501. In this step, the semiconductor substrate SB in which the impurity implantation regions 26 (FIGS. 15 and 16) have been formed is annealed. This activates the implanted impurities to form the first bottom diffusion layers 14, the first sidewall diffusion layers 16a, the second bottom diffusion layer 17, and the second sidewall diffusion layer 16b. As describe above, the fourth step (FIGS. 13 and 14) and the fifth step (FIGS. 15 and 16) are performed separately. Thus, a plurality of ion implantation steps having different ion implantation directions are performed to form the second sidewall diffusion layer 16b on the second sidewall SW2 of the second trench TR2. Example impurity ions to be used in the ion implantation steps include aluminum ions. Each implantation energy for implanting ions is set in consideration of influences on the main breakdown voltage and the ON resistance so that diffusive broadening of p-type impurity diffusion layers in a depth direction and an in-plane direction, which are formed through this ion implantation, sufficiently prevents field concentration on the gate insulating film 7 of the semiconductor device 501.

The p channel doped layer 4, the n⁺ source layer 5, and the p⁺ contact layer 6 in the semiconductor substrate SB of the semiconductor device 501 can be formed through the photolithography, the ion implantation technology, and the annealing technology. These layers may be formed before the fourth step (FIGS. 13 and 14). When ions are implanted before the sixth step (FIGS. 17 and 18) to form these layers, the sixth step can also serve as annealing these for formation. Since the subsequent steps can be performed through general semiconductor manufacturing technology, the description is omitted. Furthermore, methods of manufacturing semiconductor devices 502 to 504 according to Embodiments 2 to 4, respectively, which will be described later, can be performed by modifying fabrication patterns in the method of manufacturing the semiconductor device 501 according to Embodiment 1. Thus, the description is omitted.

Next, operations of the semiconductor device 501 will be described hereinafter. As describe above, the semiconductor device 501 has a MOSFET structure including the n⁺ source layer 5, the p channel doped layer 4, the n⁻ drift layer 3, the gate insulating film 7, and the gate buried portions 18b of the gate electrode 18. When a positive voltage higher than or equal to a threshold voltage of the MOSFET structure is applied to the gate electrode 18, the MOSFET structure enters an ON state. This causes the drain voltage to drop, and causes the main current to flow between the source electrode 11 and the drain electrode 12. Conversely, when a positive voltage lower than or equal to the threshold voltage of the MOSFET structure or a negative voltage is applied to the gate electrode 18, the MOSFET structure enters an OFF state. This causes the drain voltage to rise, and interrupts the current from passing between the source electrode 11 and the drain electrode 12.

Next, a problem that may arise from general MOSFETs will be hereinafter described. When the drain voltage rises due to, for example, the aforementioned switching operation, a voltage shared by the gate insulating film 7 in contact with the n-drift layer 3 also rises. Thus, the field strength to be applied to the gate insulating film 7 increases. Generally, the vicinity of trenches formed in a boundary between the breakdown voltage holding region RIv and the active region RA is subject to electrical fields of the semiconductor substrate SB in the thickness direction and the in-plane direction, and is greatly influenced by these fields. When the potential of a p-type diffusion layer disposed at the bottom of each of the trenches increases due to the rise in the drain voltage, the electrical field to be applied to the gate insulating film at the bottom of the trench is intensified.

In the structure of the semiconductor device 501 according to Embodiment 1, the second sidewall diffusion layer 16b disposed on the second sidewall SW2 of the second trench TR2 is in contact with each of the second bottom diffusion layer 17 disposed at least in a part of the second bottom BT2 of the second trench TR2 and the p channel doped layer 4 having a source potential (more generally speaking, a potential of the source electrode 11). Consequently, the second sidewall SW2 in contact with the active region RA and the second bottom BT2 extending from the second sidewall SW2 toward the inactive region RI can avoid excessive potential rise, through electrical connection to the source potential (more generally speaking, the potential of the source electrode 11). Accordingly, dielectric breakdown of an insulating film (i.e., the gate insulating film 7 or the field insulating film 20) facing the gate electrode 18 in the vicinity of a boundary between the active region RA and the inactive region RI can be prevented. Furthermore, prevention of the excessive potential rise can avoid malfunctions of the semiconductor device.

The second sidewall diffusion layer 16b may be disposed on each of the longitudinal portion SW2a and the lateral portion SW2b of the second sidewall SW2 of the second trench TR2. Consequently, both of the longitudinal portion SW2a and the lateral portion SW2b of the second sidewall SW2 can avoid the excessive potential rise.

The second trench TR2 may surround the active region RA in a plan view. This can consequently dispose a region in which the excessive potential rise can be avoided, around the active region RA.

The p⁺ contact layer 6 of p-type is in contact with the contact portions CTs and the second sidewall diffusion layer 16b. This enables the second sidewall diffusion layer 16b to be electrically connected to the source potential (more generally speaking, the potential of the source electrode 11) via a short electrical path passing through the p⁺ contact layer 6. Thus, the excessive potential rise in the second sidewall diffusion layer 16b can be more reliably avoided.

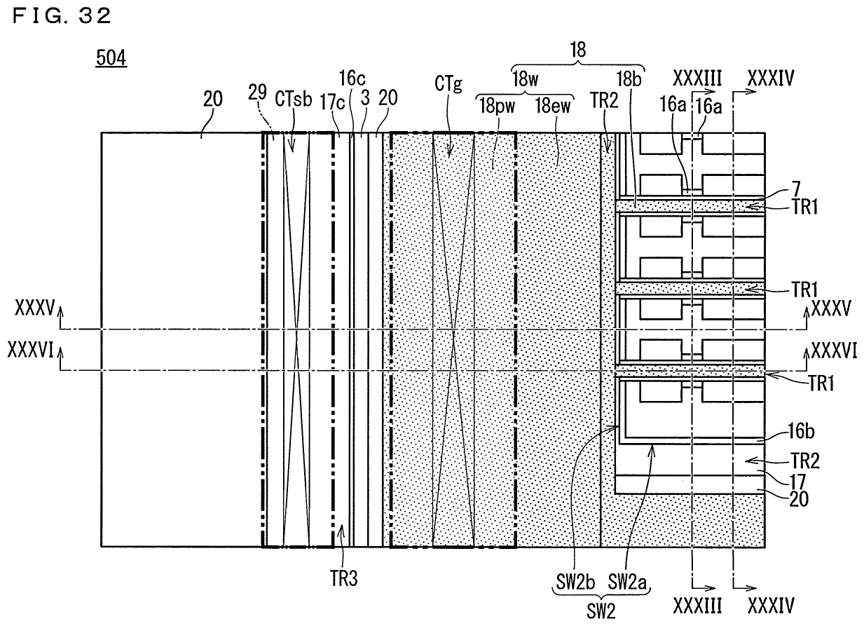

The plurality of first trenches TR1 may be directly connected to the second trench TR2. This enables a p-type diffusion layer disposed in the second trench TR2 or an additional trench (e.g. see a third trench TR3 (FIGS. 32, 35, and 36 (to be described in Embodiment 4)) to be continuously formed from one or each of the first bottom diffusion layers 14 and the first sidewall diffusion layers 16a of the first trenches TR1.

A ratio of an area of the second sidewall diffusion layer 16b to the total area of the second sidewall SW2 of the second trench TR2 may be higher than a ratio of an area of the first sidewall diffusion layers 16a to the total area of the first sidewalls SW1 of the first trenches TR1. Consequently, advantages of the second sidewall diffusion layer 16b can suffice. This will be additionally described hereinafter.

With reference to FIG. 2, a length L1, a length Lp1, a length L2, and a length Lp2 indicate the following details:
L1 indicates a pitch of a repeated pattern in the active region RA in a plan view;
Lp1 indicates a pattern length of the first sidewall diffusion layer 16a in the repeated pattern in the active region RA in a plan view;
L2 indicates a pitch of a repeated pattern of the second trench TR2 in a plan view; and
Lp2 indicates a pattern length of the second sidewall diffusion layer 16b in the repeated pattern of the second trench TR2 in a plan view.

Here, the first trenches TR1 have approximately uniform depths, and it is probably allowed to approximate the second trench TR2 having the approximately uniform depth. Thus, defining a ratio of an area of the first sidewall diffusion layers 16a to the total area of the first sidewalls SW1 of the first trenches TR1 as R1, and defining a ratio of an area of the second sidewall diffusion layer 16b to the total area of the longitudinal portion SW2a of the second sidewall SW2 of the second trench TR2 as R2, the following relationship holds:

R1=Lp1/L1; and

R2=Lp2/L2.

If a relationship R2>R1 is satisfied between the ratio R1 and the ratio R2, a potential of the vicinity of the longitudinal portion SW2a of the second sidewall SW2 is stably grounded at the source potential. Here, only the longitudinal portion SW2a of the second sidewall SW2 is focused and described in detail. Even when the entire second sidewall SW2 is focused and the ratio R2 is calculated, almost the same holds true.

Since the ratio R1 in proportion to a rate in which the first sidewall diffusion layers 16a are formed may be relatively small, a relatively high forming rate of not the first sidewall diffusion layers 16a but the n⁺ source layer 5 can be ensured. Since not the first sidewall diffusion layers 16a but the n⁺ source layer 5 actually functions as the MOSFET structure, the semiconductor device 501 can obtain a sufficiently low ON resistance by ensuring the relatively high forming rate of the n⁺ source layer 5. Thus, the semiconductor device 501 can obtain a sufficiently low ON resistance while preventing the dielectric breakdown, with the advantages of Embodiment 1.

In the method of manufacturing the semiconductor device 501 according to Embodiment 1, steps of forming the first sidewall diffusion layers 16a and the second sidewall diffusion layer 16b are performed by obliquely implanting ions into the first sidewalls SW1 of the first trenches TR1 and the second sidewall SW2 of the second trench TR2, respectively. Consequently, only implanting ions from the inner surfaces of the first trenches TR1 and the second trench TR2 into relatively shallow regions can form desired impurity diffusion layers. Thus, ions need not be implanted with high energy. Firstly, an ion implanter for high energy is no longer necessary. Secondly, a implantation mask thick enough to withstand ion implantation with high energy is no longer necessary. Thirdly, crystal defects of semiconductors caused by high energy can be prevented.

The step of implanting ions into the longitudinal portion SW2a of the second sidewall SW2 of the second trench TR2 may be performed separately from the step of implanting ions into the lateral portion SW2b of the second sidewall SW2 of the second trench TR2. This can stably form the second sidewall diffusion layer 16b on each of the longitudinal portion SW2a and the lateral portion SW2b.

The steps of forming the first sidewall diffusion layers 16a and the second sidewall diffusion layer 16b may be performed simultaneously, through simultaneous execution of the steps of forming the first trenches TR1 and the second trench TR2 in the semiconductor substrate SB and by obliquely implanting ions into the first sidewalls SW1 of the first trenches TR1 and the second sidewall SW2 of the second trench TR2. This can suppress an increase in the manufacturing cost for adding the second trench TR2 and the second sidewall diffusion layer 16b to a typical semiconductor device including the first trenches TR1 and the first sidewall diffusion layers 16a.

Embodiment 1 describes the first conductivity type as n-type and the second conductivity type as p-type. The first conductivity type may be p-type and the second conductivity type may be n-type as a modification. This modification is applicable to other Embodiments.

In the semiconductor device 501 according to Embodiment 1, the second semiconductor region (the n⁺ substrate 1 in Embodiment 1) has the first conductivity type to form a MOSFET (more generally speaking, a metal-insulator semiconductor field-effect transistor (MISFET)). As a modification to this, the second semiconductor region may have the second conductivity type to form an IGBT as a semiconductor device. This modification is applicable to other Embodiments.

### Embodiment 2

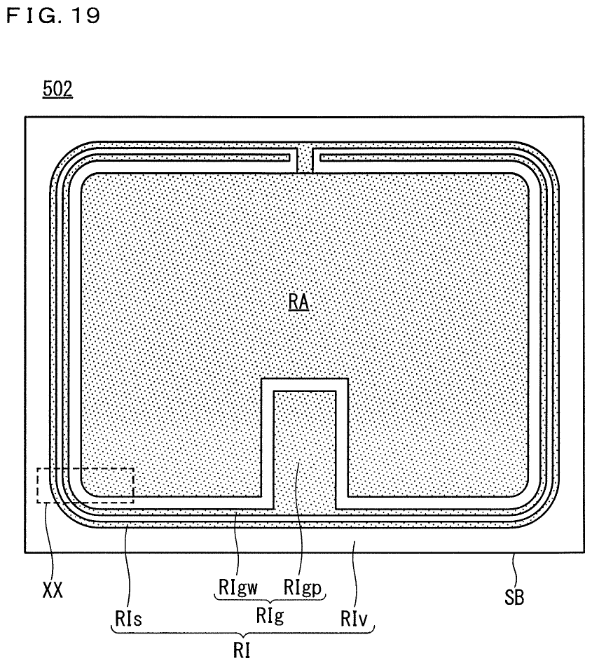

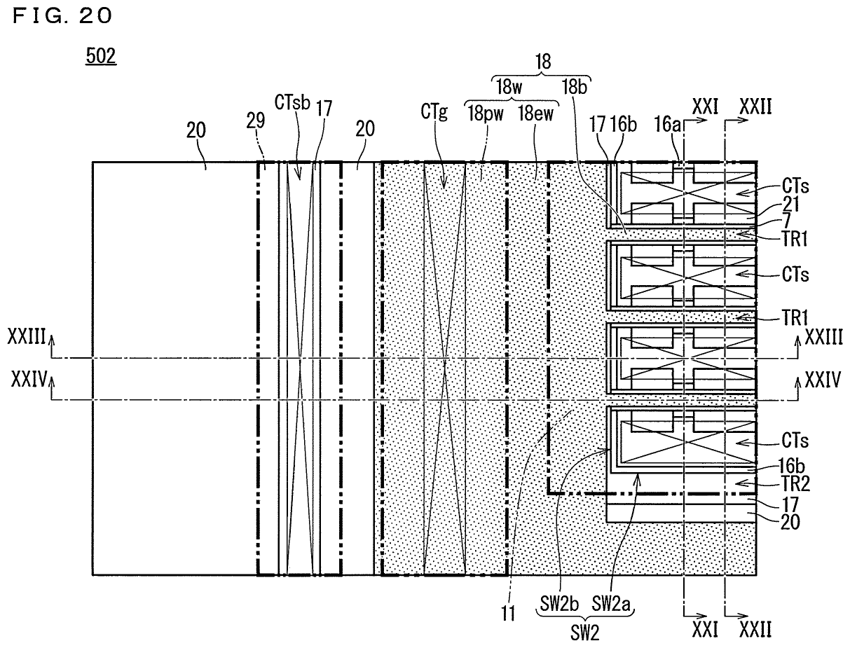

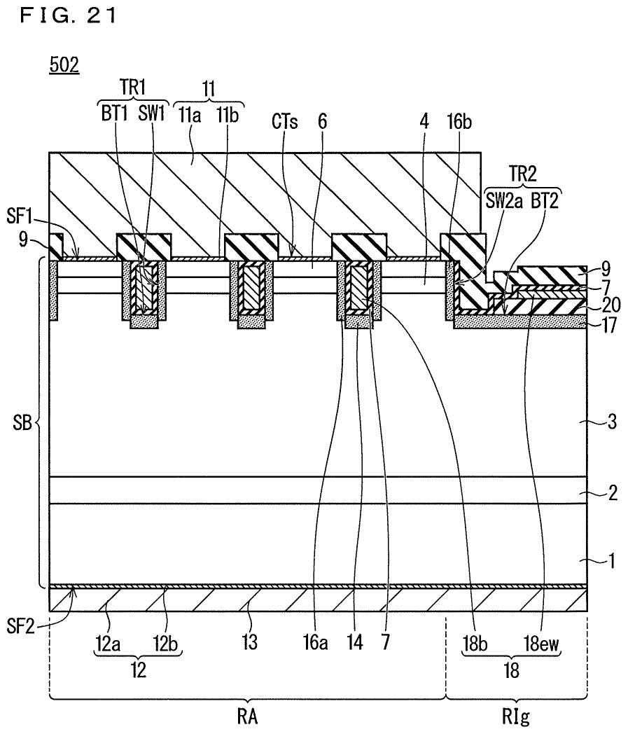

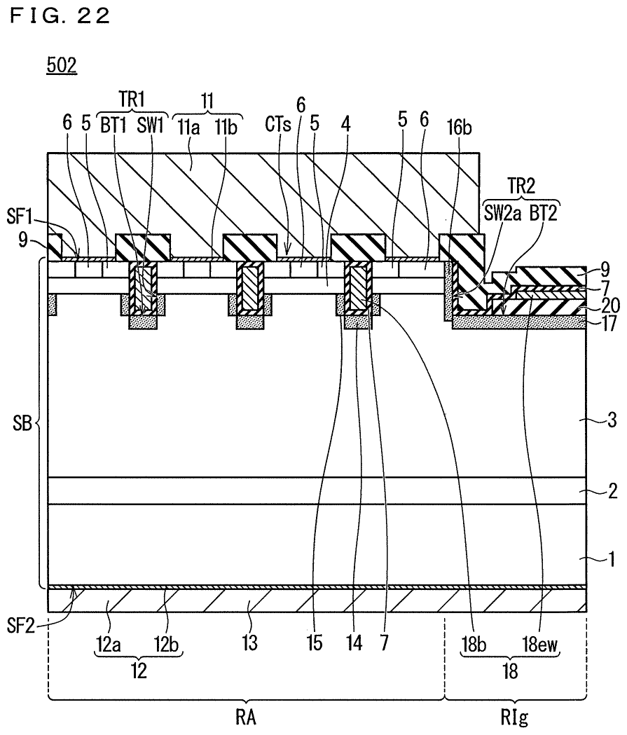

FIG. 19 is a plan view schematically illustrating a layout of a semiconductor device 502 according to Embodiment 2. FIG. 20 is a partial plan view of a dashed line region XX in FIG. 19 which schematically illustrates a structure of the semiconductor device 502. FIG. 21 is a partial cross-sectional view taken along the line XXI-XXI in FIG. 20 which schematically illustrates the structure of the semiconductor device 502. FIG. 22 is a partial cross-sectional view taken along the line XXII-XXII in FIG. 20 which schematically illustrates the structure of the semiconductor device 502. FIG. 23 is a partial cross-sectional view taken along the line XXIII-XXIII in FIG. 20 which schematically illustrates the structure of the semiconductor device 502. FIG. 24 is a partial cross-sectional view taken along the line XXIV-XXIV in FIG. 20 which schematically illustrates the structure of the semiconductor device 502. The dotted pattern in FIG. 19 illustrates an example electrode pattern on the upper surface SF1 of the semiconductor substrate SB. The dotted pattern in FIG. 20 illustrates a pattern of the gate buried portions 18b and the interconnection 18ew that are parts of the gate electrode 18 (typically, a pattern of a polysilicon layer). FIG. 20 illustrates, using two-dot chain lines, only edges of the gate surface electrode 18pw of the gate electrode 18 and the source electrode 11 to facilitate viewing of an internal structure of the semiconductor device 502. FIG. 20 omits the illustration of the interlayer insulating film 9, and illustrates the contact portions CTs, the contact portion CTg, and a contact portion CTsb penetrating the interlayer insulating film 9, using rectangles with X marks.

Each of the breakdown voltage holding region RIv, the source line region RIs, and the interconnection region RIgw (FIG. 19) is disposed in the second trench TR2 of the semiconductor device 502. In the breakdown voltage holding region RIv, regions for maintaining the breakdown voltage are preferably formed on the upper surface SF1 by doping impurities. For example, the FLRs 27 and a channel stopper layer 28 are disposed on the upper surface SF1 as illustrated in FIGS. 23 and 24. The source line portion 29 (FIGS. 23 and 24) disposed in the source line region RIs (FIG. 1) is a part of the source electrode 11, and extends from a portion of the source electrode 11 disposed in the active region RA. The source line portion 29 may include a silicide layer 29b in contact with the semiconductor substrate SB, and a non-silicide layer 29a laminated on the silicide layer 29b. The source line portion 29 of the source electrode 11 may include the contact portion CTsb in contact with the second bottom diffusion layer 17.

Since the structure other than the described structure is the same as that according to Embodiment 1, the description is not repeated.

Each of the breakdown voltage holding region RIv, the source line region RIs, and the interconnection region RIgw (FIG. 19) is disposed in the second trench TR2 according to Embodiment 2. Consequently, field concentration on each of these can hardly occur, using the second trench TR2. Thus, the semiconductor device 502 can stably maintain the main breakdown voltage (a breakdown voltage between the source electrode 11 and the drain electrode 12) while preventing dielectric breakdown of an insulating film facing the gate electrode 18.

### Embodiment 3

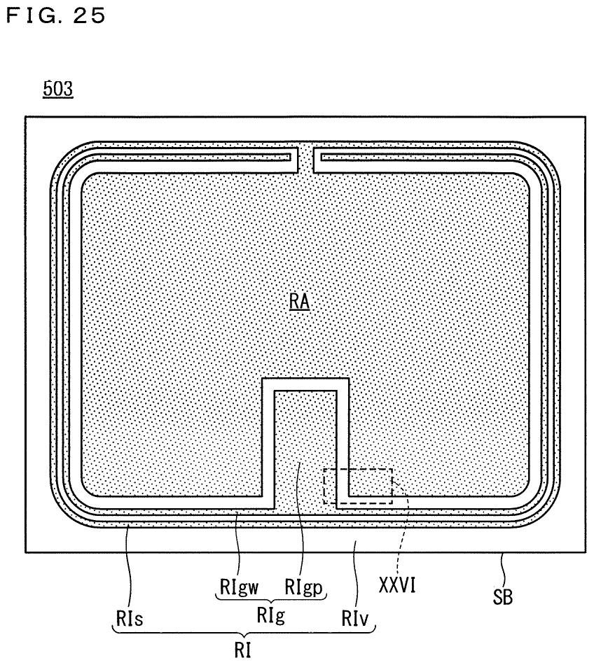

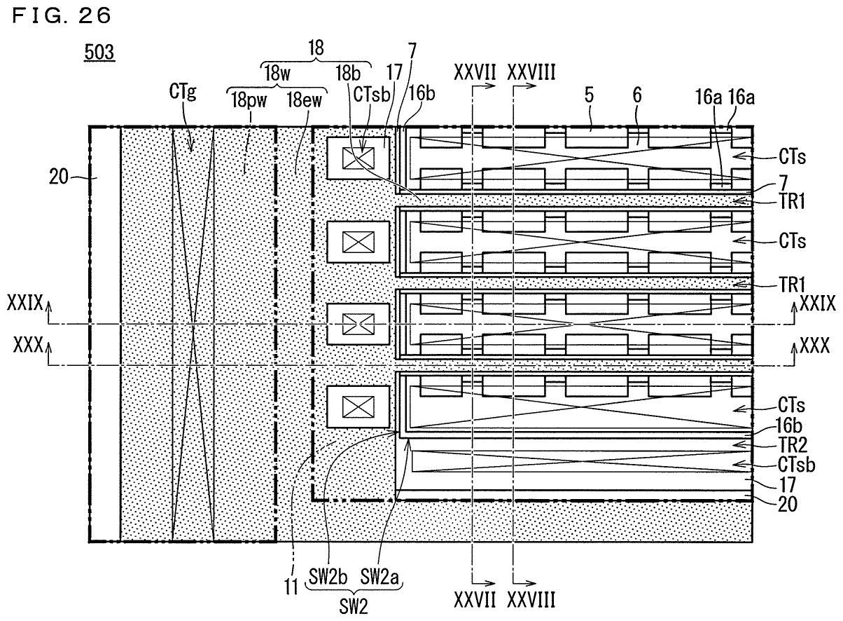

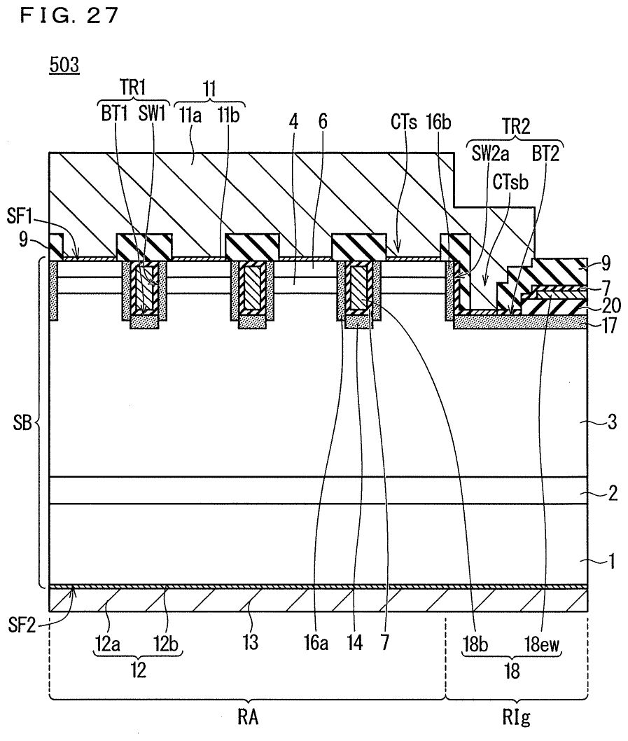

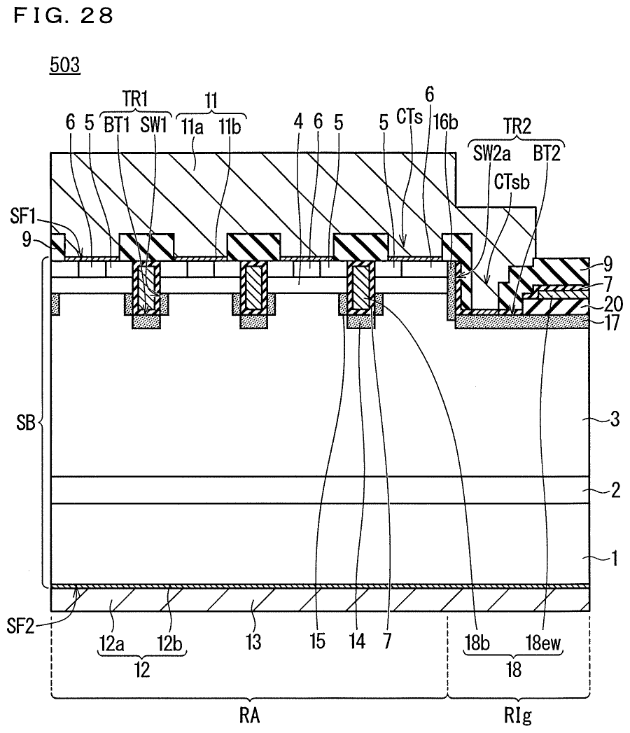

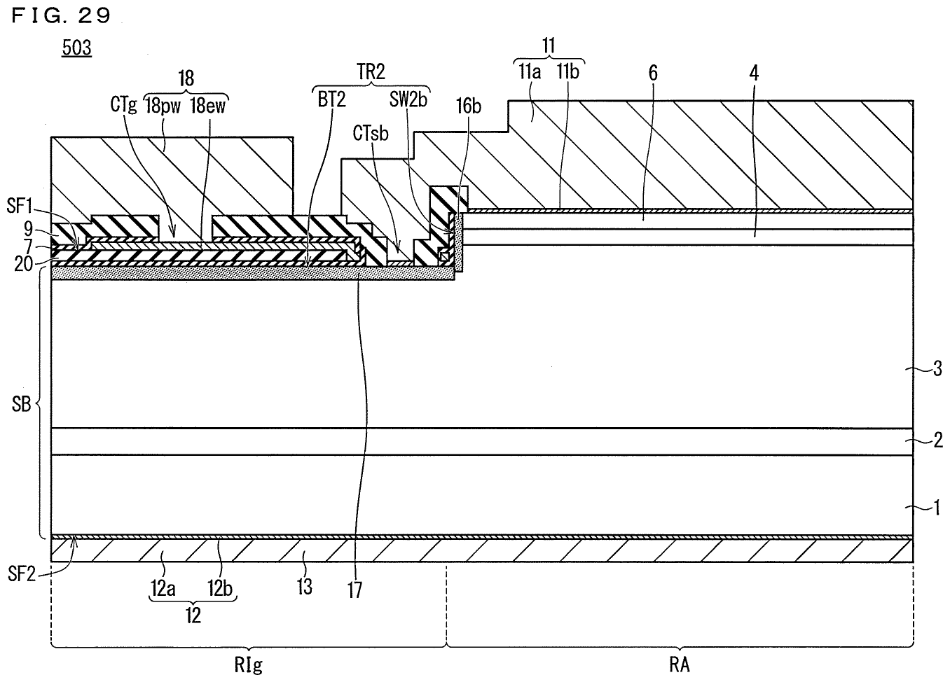

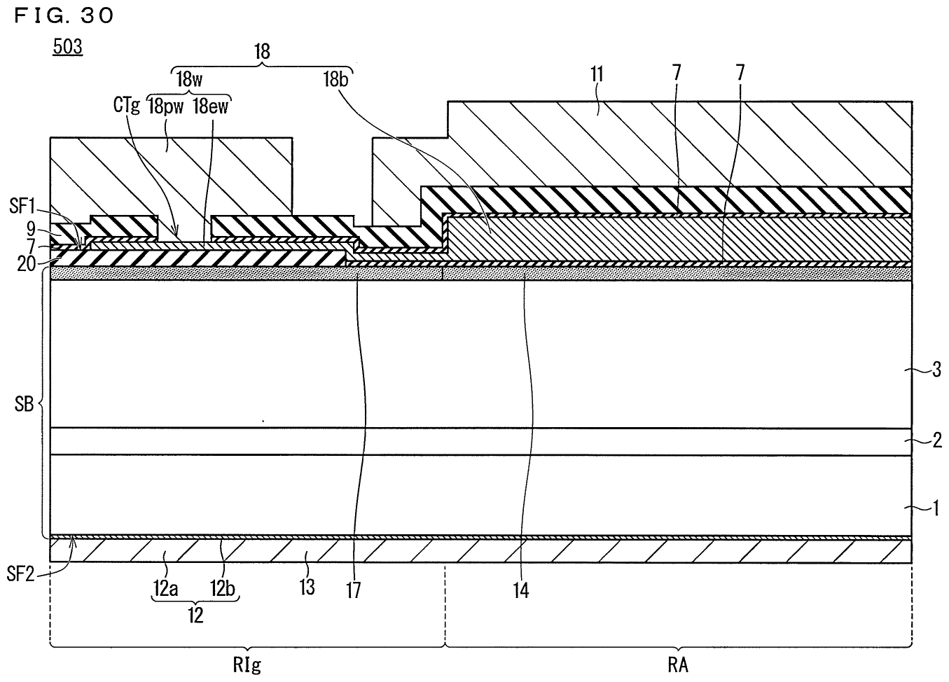

FIG. 25 is a plan view schematically illustrating a layout of a semiconductor device 503 according to Embodiment 2. FIG. 26 is a partial plan view of a dashed line region XXVI in FIG. 25 which schematically illustrates a structure of the semiconductor device 503. FIG. 27 is a partial cross-sectional view taken along the line XXVII-XXVII in FIG. 26 which schematically illustrates the structure of the semiconductor device 503. FIG. 28 is a partial cross-sectional view taken along the line XXVIII-XXVIII in FIG. 26 which schematically illustrates the structure of the semiconductor device 503. FIG. 29 is a partial cross-sectional view taken along the line XXIX-XXIX in FIG. 26 which schematically illustrates the structure of the semiconductor device 503. FIG. 30 is a partial cross-sectional view taken along the line XXX-XXX in FIG. 26 which schematically illustrates the structure of the semiconductor device 503. The dotted pattern in FIG. 25 illustrates an example electrode pattern on the upper surface SF1 of the semiconductor substrate SB. The dotted pattern in FIG. 26 illustrates a pattern of the gate buried portions 18b and the interconnection 18ew that are parts of the gate electrode 18 (typically, a pattern of a polysilicon layer). FIG. 26 illustrates, using two-dot chain lines, only edges of the gate surface electrode 18pw of the gate electrode 18 and the source electrode 11 to facilitate viewing of an internal structure of the semiconductor device 503. FIG. 26 omits the illustration of the interlayer insulating film 9, and illustrates the contact portions CTs and the contact portion CTg penetrating the interlayer insulating film 9, using rectangles with X marks.

The source electrode 11 of the semiconductor device 503 includes contact portions CTsb in contact with the second bottom diffusion layer 17 of the semiconductor substrate SB. The contact portion CTsb is disposed between the gate electrode 18 and the second sidewall SW2 of the second trench TR2 on the upper surface SF1 (i.e., in a plan view) with reference to a cross-sectional view in FIG. 29. Unlike FIG. 23 (Embodiment 2), the gate electrode 18 is not interposed in this structure between the contact portion CTsb and the second sidewall SW2 of the second trench TR2 on the upper surface SF1 (i.e., in a plan view). Thus, the contact portion CTsb can be disposed closer to the second sidewall diffusion layer 16b in Embodiment 3. The following will describe how much closer to the second sidewall diffusion layer 16b the contact portion CTsb should be preferably disposed.

The plurality of first trenches TR1 are aligned at regular intervals in the lateral direction on the upper surface SF1 of the semiconductor substrate SB. One of the regular intervals is a dimension between the right end of the opening of the first trench TR1 to the left and the left end of the opening of the first trench TR1 in the middle, with reference to FIG. 27. In other words, the interval is a width of a mesa portion of the semiconductor substrate SB between the adjacent first trenches TR1 on the upper surface SF1. In a plan view, a distance between the contact portion CTsb and the second sidewall SW2 on which the second sidewall diffusion layer 16b is disposed is preferably smaller than the interval.

Since the structure other than the described structure is the same as that according to Embodiment 1, the description is not repeated.

The contact portion CTsb according to Embodiment 3 can directly connect the second bottom diffusion layer 17 to the source electrode 11 with the source potential (more generally speaking, the potential of the source electrode 11). Thus, the excessive potential rise in the second bottom diffusion layer 17 can be more reliably avoided. Here, a distance between the contact portion CTsb in the source electrode 11 and the second sidewall SW2 on which the second sidewall diffusion layer 16b is disposed may be smaller than the aforementioned interval. This enables the second sidewall diffusion layer 16b to be electrically connected to the source electrode 11 with the source potential (more generally speaking, the potential of the source electrode 11) via a short electrical path. Thus, the excessive potential rise in the second sidewall diffusion layer 16b can be more reliably avoided.

### Embodiment 4

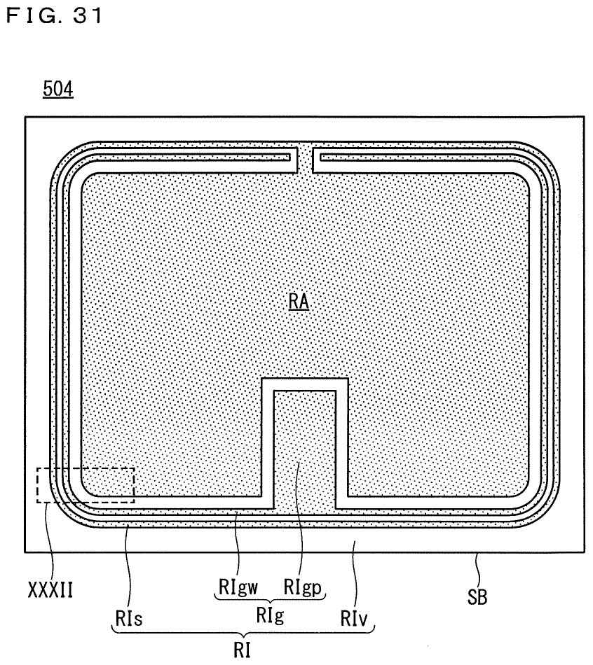

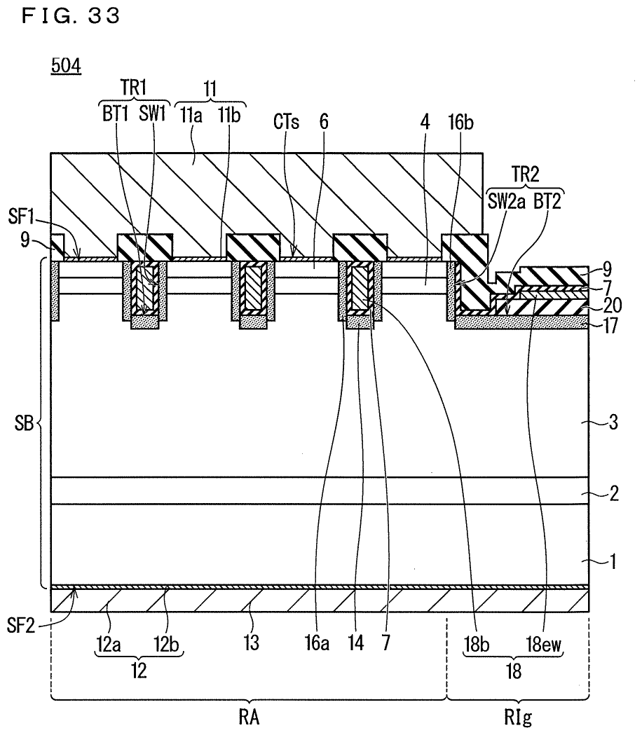

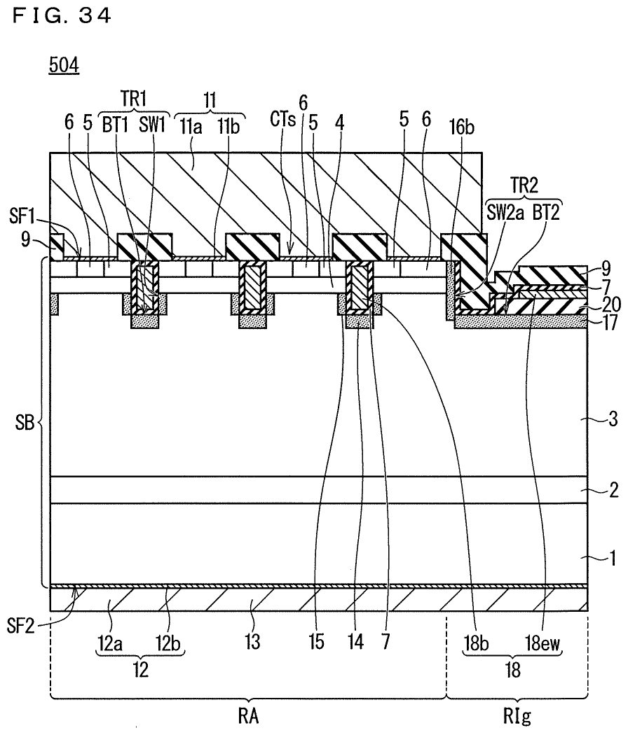

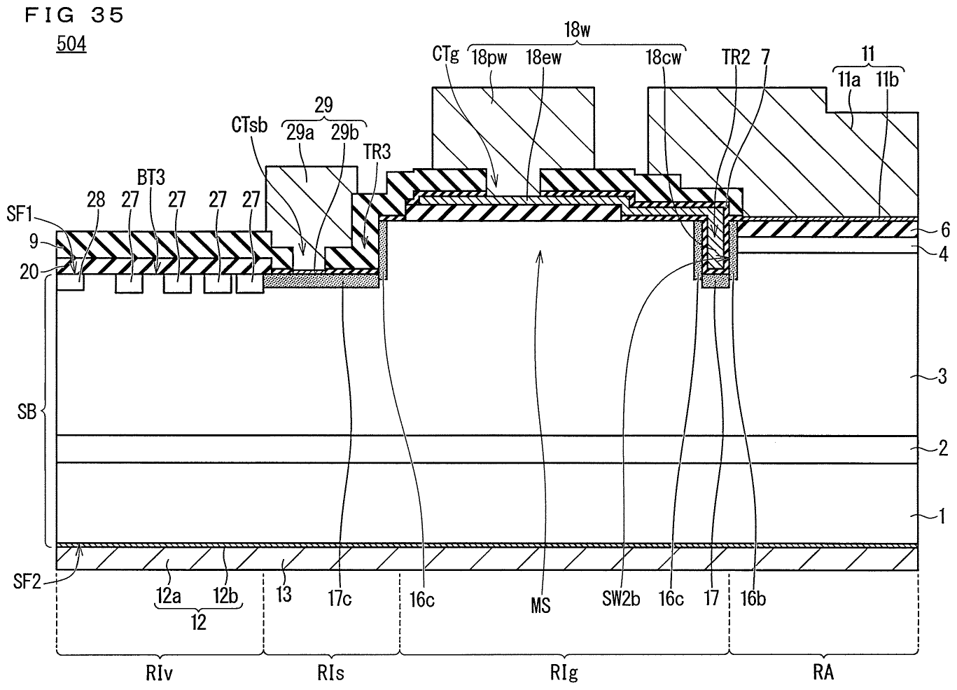

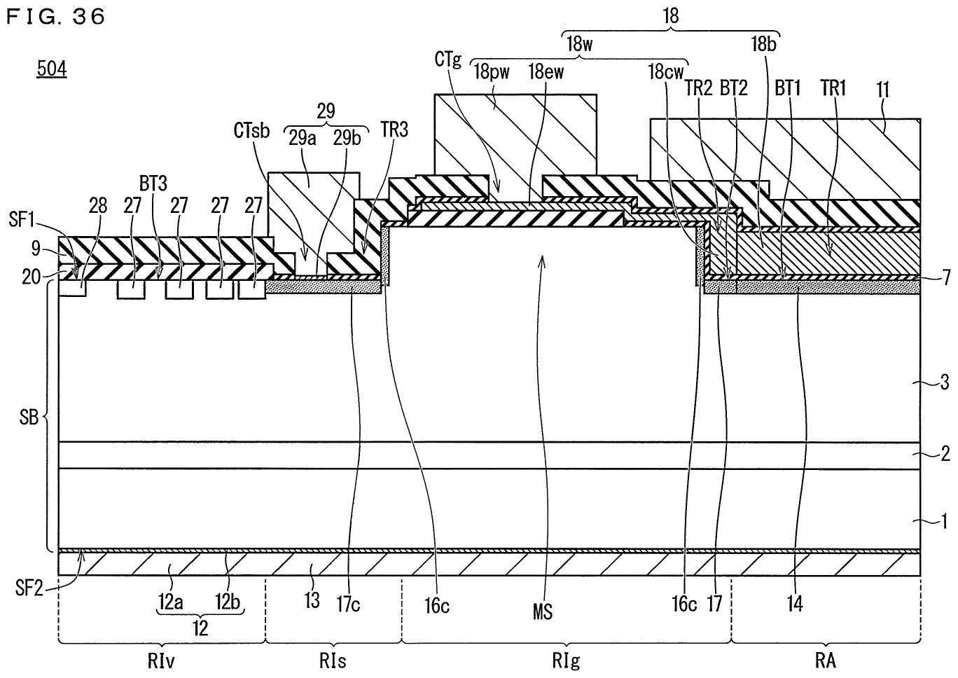

FIG. 31 is a plan view schematically illustrating a layout of a semiconductor device 504 according to Embodiment 4. FIG. 32 is a partial plan view of a dashed line region XXXII in FIG. 31 which schematically illustrates a structure of the semiconductor device 504. FIG. 33 is a partial cross-sectional view taken along the line XXXIII-XXXIII in FIG. 32 which schematically illustrates the structure of the semiconductor device 504. FIG. 34 is a partial cross-sectional view taken along the line XXXIV-XXXIV in FIG. 32 which schematically illustrates the structure of the semiconductor device 504. FIG. 35 is a partial cross-sectional view taken along the line XXXV-XXXV in FIG. 32 which schematically illustrates the structure of the semiconductor device 504. FIG. 36 is a partial cross-sectional view taken along the line XXXVI-XXXVI in FIG. 32 which schematically illustrates the structure of the semiconductor device 504. The dotted pattern in FIG. 31 illustrates an example electrode pattern on the upper surface SF1 of the semiconductor substrate SB. The dotted pattern in FIG. 32 illustrates a pattern of the gate buried portions 18b and the interconnection 18ew that are parts of the gate electrode 18 (typically, a pattern of a polysilicon layer). Since the structure of the source electrode 11 of the semiconductor device 504 is approximately the same as that in FIG. 20 according to Embodiment 2, FIG. 32 omits the illustration. FIG. 32 illustrates only the edge of the gate surface electrode 18pw of the gate electrode 18 using a two-dot chain line, omits the illustration of the interlayer insulating film 9, and illustrates the contact portion CTg and the contact portion CTsb penetrating the interlayer insulating film 9, using rectangles with X marks.

As described in Embodiment 3, the plurality of first trenches TR1 are aligned at regular intervals in the lateral direction on the upper surface SF1 of the semiconductor substrate SB. The semiconductor substrate SB includes a third trench TR3 on the upper surface SF1 in the inactive region RI. The third trench TR3 includes a third bottom BT3. The third trench TR3 is separated from the second trench TR2 so that a mesa portion MS of the semiconductor substrate SB is formed between the third trench TR3 and the second trench TR2. The third trench TR3 is separated from the second trench TR2 at a distance longer than or equal to one of the regular intervals. The mesa portion MS is not limited to specific use but is used as a place on which the interconnection 18ew of the gate electrode 18 is disposed in Embodiment 4.

The breakdown voltage holding region RIv is disposed on the third bottom BT3 of the third trench TR3 according to Embodiment 4. Specifically, the FLRs 27 and the channel stopper layer 28 are formed on the third bottom BT3 as described in Embodiment 2.

Since the structure other than the described structure is the same as that according to Embodiment 1 or 2, the description is not repeated.

In Embodiment 4, the third trench TR3 is separated from the second trench TR2 at a distance longer than or equal to one of the regular intervals of the first trenches TR1. Consequently, the mesa portion MS has the mechanical strength approximately identical to that of the mesa portion between the first trenches TR1. This prevents the mesa portion MS from being damaged due to, for example, thermal stress.

### Embodiment 5

Embodiment 5 will describe a power conversion device to which one of the semiconductor devices 501 to 504 according to Embodiments 1 to 4 is applied. Although this application is not limited to specific power conversion devices, Embodiment 5 will describe application of one of the semiconductor devices 501 to 504 according to Embodiments 1 to 4 to a three-phase inverter.

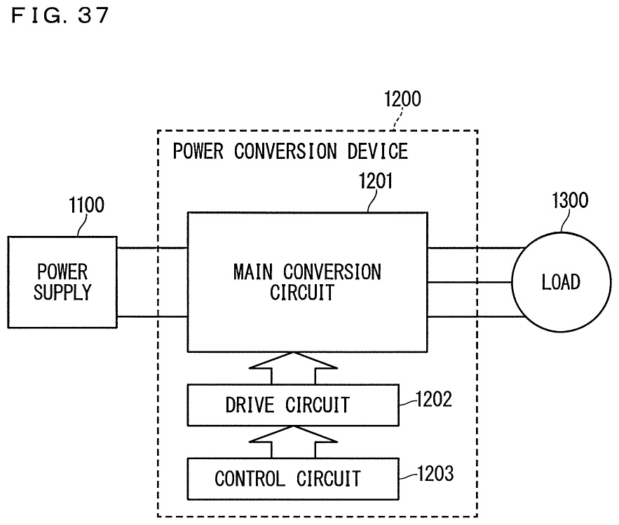

FIG. 37 is a block diagram illustrating a configuration of a power conversion system to which a power conversion device 1200 according to Embodiment 5 is applied.

The power conversion system illustrated in FIG. 37 includes a power supply 1100, a power conversion device 1200, and a load 1300. The power supply 1100, which is a DC power supply, supplies a DC power to the power conversion device 1200. The power supply 1100 may include various components such as a DC system, a solar battery, or a rechargeable battery, or a rectifying circuit connected to an AC system and an AC/DC converter. The power supply 1100 may include a DC/DC converter which converts the DC power output from the DC system into a predetermined power.

The power conversion device 1200, which is a three-phase inverter connected between the power supply 1100 and the load 1300, converts the DC power supplied from the power supply 1100 into the AC power to supply the AC power to the load 1300. As illustrated in FIG. 37, the power conversion device 1200 includes a main conversion circuit 1201 that converts the input DC power to the AC power to be output, a drive circuit 1202 that outputs a driving signal for driving each switching element in the main conversion circuit 1201, and a control circuit 1203 that outputs, to the drive circuit 1202, a control signal for controlling the drive circuit 1202.

The load 1300 is not limited to specific use but is a three-phase electrical motor driven by the AC power supplied from the power conversion device 1200 in Embodiment 5. The electrical motor may be mounted on various types of electrical devices, and is used as an electrical motor for, for example, a hybrid car, an electrical car, a rail vehicle, an elevator, or air-conditioning equipment.

The power conversion device 1200 will be described in detail hereinafter. The main conversion circuit 1201 includes switching elements and freewheeling diodes (not illustrated). Switching of the switching element causes the DC power supplied from the power supply 1100 to be converted into the AC power. The AC power is then supplied to the load 1300. The specific circuit configuration of the main conversion circuit 1201 is of various types. The main conversion circuit 1201 according to Embodiment 5 is a three-phase full-bridge circuit having two levels, and can include six switching elements and six freewheeling diodes anti-parallel connected to the respective switching elements. One of the semiconductor devices 501 to 504 according to Embodiments 1 to 4 is applied to each of the switching elements in the main conversion circuit 1201. The six switching elements are used as three pairs of the switching elements. The pair of the two switching elements forms a pair of upper and lower arms serially connected to each other. Thus, each of the three pairs of the switching elements of the upper and lower arms forms a corresponding phase (U phase, V phase, or W phase) of a full bridge circuit. Output terminals of the respective pairs of upper and lower arms, i.e., three output terminals of the main conversion circuit 1201 are connected to the load 1300.

The drive circuit 1202 generates driving signals for driving the switching elements of the main conversion circuit 1201, and supplies the driving signals to control electrodes of the switching elements of the main conversion circuit 1201. Specifically, the drive circuit 1202 outputs, to the control electrode of each of the switching elements in accordance with the control signal from the control circuit 1203 to be described hereinafter, the driving signal for switching the switching element to an ON state and the driving signal for switching the switching element to an OFF state. When the switching element is kept in the ON state, the driving signal is a voltage signal (ON signal) higher than or equal to a threshold voltage of the switching element. When the switching element is kept in the OFF state, the driving signal is a voltage signal (OFF signal) lower than the threshold voltage of the switching element.

The control circuit 1203 controls the switching elements of the main conversion circuit 1201 so that a desired power is supplied to the load 1300. Specifically, the control circuit 1203 calculates a time (ON time) when each of the switching elements of the main conversion circuit 1201 needs to enter the ON state, based on the power which needs to be supplied to the load 1300. For example, the control circuit 1203 can control the main conversion circuit 1201 by performing PWM control for modulating the ON time of the switching elements in accordance with the voltage which needs to be output. Then, the control circuit 1203 outputs a control instruction (control signal) to the drive circuit 1202 so that the drive circuit 1202 outputs the ON signal to the switching element which needs to enter the ON state and outputs the OFF signal to the switching element which needs to enter the OFF state at each time. The drive circuit 1202 outputs the ON signal or the OFF signal as the driving signal to the control electrode of each of the switching elements in accordance with this control signal.

The power conversion device according to Embodiment 5 can enhance the reliability with application of one of the semiconductor devices 501 to 504 according to Embodiments 1 to 4 to each of the switching elements in the main conversion circuit 1201.

Although Embodiment 5 describes the application of the semiconductor devices 501 to 504 according to Embodiments 1 to 4 to the three-phase inverter having the two levels, Embodiment 5 is not limited to specific power conversion devices, but is applicable to various power conversion devices. The power conversion device may be, for example, a multi-level power conversion device of a three-level or higher, instead of the two-level power conversion device. The power conversion device may be a single-phase inverter when the power is supplied to a single-phase load. Moreover, one of the semiconductor devices 501 to 504 according to Embodiments 1 to 4 is also applicable to a DC/DC converter or an AC/DC converter when the power is supplied to, for example, a DC load.

The load to which the power conversion device supplies power is not limited to the electrical motor but, for example, an electrical discharge machine, a laser beam machine, an induction heat cooking device, or a non-contact power feeding system. The power conversion device can be further used as a power conditioner of, for example, a solar power system or an electricity storage system.

Embodiments can be freely combined, and appropriately modified or omitted.

### APPENDIXES

A summary of various aspects of the present disclosure will be hereinafter described as Appendixes.

### APPENDIX 1

A semiconductor device (501 to 504) including an active region (RA) and an inactive region (RI) in a plan view, the inactive region (RI) including a breakdown voltage holding region (RIv) and a gate line region (RIg), the gate line region being in contact with the active region (RA), the semiconductor device comprising:
a semiconductor substrate (SB) having a first main surface (SF1) and a second main surface (SF2) opposite to the first main surface (SF1);
a first electrode (11) disposed on the first main surface (SF1) of the semiconductor substrate (SB);
a second electrode (12) disposed on the second main surface (SF2) of the semiconductor substrate (SB);
an insulating film on the first main surface (SF1) of the semiconductor substrate (SB); and
a gate electrode (18) on the first main surface (SF1) through the insulating film,
wherein the semiconductor substrate (SB) includes:
   a drift layer (3) of a first conductivity type, the drift layer (3) being disposed in the active region (RA) and the inactive region (RI);
   a base region (4) of a second conductivity type different from the first conductivity type, the base region (4) being disposed in the active region (RA) between the drift layer (3) and the first main surface (SF1);
   a first semiconductor region (5) of the first conductivity type, the first semiconductor region (5) being disposed on the base region (4) in the active region (RA) and in contact with the first electrode (11);
   a plurality of first trenches (TR1) in the first main surface (SF1) in the active region (RA), the first trenches (TR1) including a first bottom (BT1) and a first sidewall (SW1), the first sidewall (SW1) being in contact with the first semiconductor region (5) and the base region (4), each of the first trenches (TR1) extending in a longitudinal direction, the first trenches (TR1) being aligned in a lateral direction crossing the longitudinal direction;
   a first bottom diffusion layer (14) of the second conductivity type, the first bottom diffusion layer (14) being disposed on the first bottom (BT1) of each of the first trenches (TR1);
   a first sidewall diffusion layer (16a) of the second conductivity type, the first sidewall diffusion layer (16a) being disposed on the first sidewall (SW1) of each of the first trenches (TR1) and in contact with the first bottom diffusion layer (14) and the base region (4);
   a second semiconductor region (1) of the first conductivity type or the second conductivity type, the second semiconductor region (1) being disposed between the drift layer (3) and the second main surface (SF2) at least in the active region (RA) and in contact with the second electrode (12);
   a second trench (TR2) in the first main surface (SF1) in the inactive region (RI), the second trench (TR2) including a second bottom (BT2) and a second sidewall (SW2), the second sidewall (SW2) including a longitudinal portion (SW2a) along the longitudinal direction and being in contact with the active region (RA) and a lateral portion (SW2b) along the lateral direction;
   a second bottom diffusion layer (17) of the second conductivity type, the second bottom diffusion layer (17) being disposed at least in a part of the second bottom (BT2) of the second trench (TR2); and
   a second sidewall diffusion layer (16b) of the second conductivity type, the second sidewall diffusion layer (16b) being disposed at least on the longitudinal portion (SW2a) or the lateral portion (SW2b) of the second sidewall (SW2) of the second trench (TR2), and being in contact with the second bottom diffusion layer (17) and the base region (4), and
wherein the gate electrode (18) includes:
   a gate buried portion (18b) buried in each of the first trenches (TR1) of the semiconductor substrate (SB) through the insulating film; and
   a gate line portion (18w) extending from the gate buried portion (18b) into the second trench (TR2), and
wherein the second bottom diffusion layer (17) is disposed at least in a portion of the second bottom (BT2) of the second trench (TR2) on which the gate line portion (18w) is disposed in the plan view.

### APPENDIX 2

The semiconductor device (501 to 504) according to appendix 1,
wherein the second sidewall diffusion layer (16b) is disposed in each of the longitudinal portion (SW2a) and the lateral portion (SW2b) of the second sidewall (SW2) of the second trench (TR2).

### APPENDIX 3

The semiconductor device according to appendix 1 or 2,
wherein the second trench (TR2) surrounds the active region (RA) in the plan view.

### APPENDIX 4

The semiconductor device according to one of appendixes 1 to 3,
wherein the first electrode (11) includes a contact portion (CTs) between the second trench (TR2) and a corresponding one of the first trenches (TR1) closest to the second trench (TR2) in the lateral direction, the contact portion (CTs) being in contact with the first main surface (SF1) of the semiconductor substrate (SB) outside the second trench (TR2), and
the semiconductor substrate (SB) includes a contact region (6) of the second conductivity type, the contact region (6) being in contact with the contact portion (CTs) and the second sidewall diffusion layer (16b).

### APPENDIX 5

The semiconductor device (503) according to one of appendixes 1 to 4,
wherein the first electrode (11) includes a contact portion (CTsb) in contact with the second bottom diffusion layer (17) of the semiconductor substrate (SB).

### APPENDIX 6

The semiconductor device according to appendix 5,
wherein the plurality of first trenches (TR1) are aligned at regular intervals in the lateral direction on the first main surface (SF1) of the semiconductor substrate (SB), and
in the plan view, a distance between the contact portion of the first electrode (11) and the second sidewall (SW2) of the second trench (TR2) is smaller than one of the regular intervals.

### APPENDIX 7

The semiconductor device according to one of appendixes 1 to 6,
wherein a ratio of an area of the second sidewall diffusion layer (16b) to a total area of the second sidewall (SW2) of the second trench (TR2) is higher than a ratio of an area of the first sidewall diffusion layers (16a) to a total area of the first sidewalls (SW1) of the first trenches (TR1).

### APPENDIX 8

The semiconductor device (501 to 503) according to one of appendixes 1 to 7,
wherein the plurality of first trenches (TR1) are directly connected to the second trench (TR2).

### APPENDIX 9

The semiconductor device (504) according to one of appendixes 1 to 8,
wherein the plurality of first trenches (TR1) are aligned at regular intervals in the lateral direction on the first main surface (SF1) of the semiconductor substrate (SB),
the semiconductor substrate (SB) includes a third trench (TR3) on the first main surface (SF1) in the inactive region (RI), the third trench (TR3) including a third bottom (BT3) and being separated from the second trench (TR2) so that a mesa portion (MS) of the semiconductor substrate (SB) is formed between the third trench (TR3) and the second trench (TR2), and
the third trench (TR3) is separated from the second trench (TR2) at a distance longer than or equal to one of the regular intervals.

### APPENDIX 10

A method of manufacturing the semiconductor device (501 to 504) according to one of appendixes 1 to 9, the method comprising:
a) forming the first trenches (TR1) and the second trench (TR2) in the semiconductor substrate (SB); and
b) obliquely implanting ions into the first sidewalls (SW1) of the first trenches (TR1) and the second sidewall (SW2) of the second trench (TR2) to form the first sidewall diffusion layers (16a) and the second sidewall diffusion layer (16b), respectively.

### APPENDIX 11

The method according to appendix 10,
wherein the b) includes:
   b1) implanting the ions into the longitudinal portion (SW2a) of the second sidewall (SW2) of the second trench (TR2); and
   b2) implanting the ions into the lateral portion (SW2b) of the second sidewall (SW2) of the second trench (TR2), and
wherein the b1) and the b2) are performed separately.

### APPENDIX 12

A power conversion device (1200), comprising:
a main conversion circuit (1201) to convert an input power to a power to be output, the main conversion circuit (1201) including the semiconductor device (501 to 504) according to one of appendixes 1 to 9;
a drive circuit (1202) to output, to the semiconductor device (501 to 504), a driving signal for driving the semiconductor device (501 to 504); and
a control circuit (1203) to output, to the drive circuit (1202), a control signal for controlling the drive circuit (1202).

While the invention has been shown and described in detail, the foregoing description is in all aspects illustrative and not restrictive. It is therefore understood that numerous modifications and variations can be devised without departing from the scope of the invention.

What is claimed is:

1. A semiconductor device including an active region and an inactive region in a plan view, the inactive region including a breakdown voltage holding region and a gate line region, the gate line region being in contact with the active region, the semiconductor device comprising:
a semiconductor substrate having a first main surface and a second main surface opposite to the first main surface;
a first electrode disposed on the first main surface of the semiconductor substrate;
a second electrode disposed on the second main surface of the semiconductor substrate;
an insulating film on the first main surface of the semiconductor substrate; and
a gate electrode on the first main surface through the insulating film,
wherein the semiconductor substrate includes:
a drift layer of a first conductivity type, the drift layer being disposed in the active region and the inactive region;
a base region of a second conductivity type different from the first conductivity type, the base region being disposed in the active region between the drift layer and the first main surface;
a first semiconductor region of the first conductivity type, the first semiconductor region being disposed on the base region in the active region and in contact with the first electrode;
a plurality of first trenches in the first main surface in the active region, the first trenches including a first bottom and a first sidewall, the first sidewall being in contact with the first semiconductor region and the base region, each of the first trenches extending in a longitudinal direction, the first trenches being aligned in a lateral direction crossing the longitudinal direction;
a first bottom diffusion layer of the second conductivity type, the first bottom diffusion layer being disposed on the first bottom of each of the first trenches;
a first sidewall diffusion layer of the second conductivity type, the first sidewall diffusion layer being disposed on the first sidewall of each of the first trenches and in contact with the first bottom diffusion layer and the base region;
a second semiconductor region of the first conductivity type or the second conductivity type, the second semiconductor region being disposed between the drift layer and the second main surface at least in the active region and in contact with the second electrode;
a second trench in the first main surface in the inactive region, the second trench including a second bottom and a second sidewall, the second sidewall including a longitudinal portion along the longitudinal direction and being in contact with the active region and a lateral portion along the lateral direction;
a second bottom diffusion layer of the second conductivity type, the second bottom diffusion layer being disposed at least in a part of the second bottom of the second trench; and
a second sidewall diffusion layer of the second conductivity type, the second sidewall diffusion layer being disposed at least on the longitudinal portion or the lateral portion of the second sidewall of the second trench, and being in contact with the second bottom diffusion layer and the base region, and
wherein the gate electrode includes:
a gate buried portion buried in each of the first trenches of the semiconductor substrate through the insulating film; and
a gate line portion extending from the gate buried portion into the second trench, and
wherein the second bottom diffusion layer is disposed at least in a portion of the second bottom of the second trench on which the gate line portion is disposed in the plan view.

2. The semiconductor device according to claim 1,
wherein the second sidewall diffusion layer is disposed on each of the longitudinal portion and the lateral portion of the second sidewall of the second trench.

3. The semiconductor device according to claim 1,
wherein the second trench surrounds the active region in the plan view.

4. The semiconductor device according to claim 1,
wherein the first electrode includes a contact portion between the second trench and a corresponding one of the first trenches closest to the second trench in the lateral direction, the contact portion being in contact with the first main surface of the semiconductor substrate outside the second trench, and
the semiconductor substrate includes a contact region of the second conductivity type, the contact region being in contact with the contact portion and the second sidewall diffusion layer.

5. The semiconductor device according to claim 1,
wherein the first electrode includes a contact portion in contact with the second bottom diffusion layer of the semiconductor substrate.

6. The semiconductor device according to claim 5,
wherein the plurality of first trenches are aligned at regular intervals in the lateral direction on the first main surface of the semiconductor substrate, and
in the plan view, a distance between the contact portion of the first electrode and the second sidewall of the second trench is smaller than one of the regular intervals.

7. The semiconductor device according to claim 1,
wherein a ratio of an area of the second sidewall diffusion layer to a total area of the second sidewall of the second trench is higher than a ratio of an area of the first sidewall diffusion layers to a total area of the first sidewalls of the first trenches.

8. The semiconductor device according to claim 1,
wherein the plurality of first trenches are directly connected to the second trench.

9. The semiconductor device according to claim 1,
wherein the plurality of first trenches are aligned at regular intervals in the lateral direction on the first main surface of the semiconductor substrate,
the semiconductor substrate includes a third trench on the first main surface in the inactive region, the third trench including a third bottom and being separated from the second trench so that a mesa portion of the semiconductor substrate is formed between the third trench and the second trench, and
the third trench is separated from the second trench at a distance longer than or equal to one of the regular intervals.

10. A method of manufacturing the semiconductor device according to claim 1, the method comprising:
a) forming the first trenches and the second trench in the semiconductor substrate; and
b) obliquely implanting ions into the first sidewalls of the first trenches and the second sidewall of the second trench to form the first sidewall diffusion layers and the second sidewall diffusion layer, respectively.

11. The method according to claim 10,
wherein the b) includes:
b1) implanting the ions into the longitudinal portion of the second sidewall of the second trench; and
b2) implanting the ions into the lateral portion of the second sidewall of the second trench, and
wherein the b1) and the b2) are performed separately.

12. A power conversion device, comprising:
a main conversion circuit to convert an input power to a power to be output, the main conversion circuit including the semiconductor device according to claim 1;
a drive circuit to output, to the semiconductor device, a driving signal for driving the semiconductor device; and
a control circuit to output, to the drive circuit, a control signal for controlling the drive circuit.
